(19) United States
(12) Patent Application Publication
(10) Pub. No.: US 2024/0065021 A1
(43) Pub. Date: Feb. 22, 2024

(54) LIGHT-EMITTING ELEMENT, LIGHT-EMITTING DEVICE, DISPLAY DEVICE, AND METHOD

(71) Applicant: SHARP KABUSHIKI KAISHA, Sakai City, Osaka (JP)

(72) Inventor: MASAYA UEDA, Sakai City, Osaka (JP)

(21) Appl. No.: 18/270,532

(22) PCT Filed: Jan. 7, 2021
(86) PCT No.: PCT/JP2021/000285

§ 371 Date: Jun. 30, 2023

(51) Int. Cl. H10K 50/813; H10K 59/122; H10K 50/822; H10K 50/16; H10K 59/131; H10K 59/35; H10K 50/15

(52) U.S. Cl. CPC H10K 50/813; H10K 59/122; H10K 50/822; H10K 50/16; H10K 59/131; H10K 59/351; H10K 50/15

(57) ABSTRACT

A light-emitting element includes: a first electrode serving as an anode; a second electrode serving a cathode; a light-emitting layer; a first insulator; and a third electrode. The light-emitting layer is positioned between the first electrode and the second electrode, and the first insulator is positioned toward the first side surface of the light-emitting layer with respect to the light-emitting layer. The third electrode is included in the first insulator, and positioned so that a first portion of the first insulator is sandwiched between the third electrode and the first side surface of the light-emitting layer.

### TECHNICAL FIELD

The present invention relates to an injection light-emitting element, a light-emitting device including the light-emitting element, a display device, and a method for producing one or more of the members included in the light-emitting device and in the display device.

### BACKGROUND ART

Non-Patent Document 1 describes an injection light-emitting element, and, in particular, a multilayer light-emitting element.

### CITATION LIST

### Patent Literature

Non-Patent Document 1: Cadmium-free quantum dots based violet light-emitting diodes: High-efficiency and brightness via optimization of organic hole transport layers (Organic Electronics Volume 25, October 2015, Pages 178-183, Qingli Lin et al.)

### SUMMARY OF INVENTION

### Technical Problem

In a multilayer light-emitting element including the light-emitting element described in Non-Patent Document 1, carriers are trapped in an interface state at an interface between such layers as a light-emitting layer and a carrier transport layer included in the light-emitting element. This might reduce efficiency in injection of the carriers into the light-emitting layer.

### Solution to Problem

Alight-emitting element according to an embodiment of the present disclosure includes: a first electrode serving as an anode; a second electrode serving as a cathode; a light-emitting layer positioned between the first electrode and the second electrode; a first insulator positioned toward a first side surface of the light-emitting layer with respect to the light-emitting layer; and a third electrode included in the first insulator, and positioned so that a first portion of the first insulator is sandwiched between the third electrode and the first side surface of the light-emitting layer.

Moreover, a method according to an embodiment of the present disclosure is devised for forming an insulator and an electrode on a substrate. The electrode is positioned in the insulator. The method includes: a first protrusion forming step of forming a first protrusion; a second protrusion forming step of forming a second protrusion on an upper surface of the first protrusion; an electrode forming step of forming the electrode on one side surface or both side surfaces of the second protrusion; and a coating layer forming step of forming a coating layer to coat the second protrusion and the electrode. The insulator includes the first protrusion, the second protrusion, and the coating layer.

### Advantageous Effects of Invention

Carriers trapped in an interface state created at an interface between functional layers of a light-emitting element are released, and efficiency in injection of the carriers into the light-emitting layer is improved.

### BRIEF DESCRIPTION OF DRAWINGS

FIG. 1 is a schematic cross-sectional view of a display device according to a first embodiment.

FIG. 2 is a schematic plan view of the display device according to the first embodiment.

FIG. 3 is an enlarged plan view of a display area of the display device according to the first embodiment.

FIG. 4 is an enlarged cross-sectional view of the display device according to the first embodiment.

FIG. 5 is another enlarged cross-sectional view of the display device according to the first embodiment.

FIG. 6 is a timing diagram showing application of a drive signal to the light-emitting element according to the first embodiment, and application of a voltage between a third electrode and a fourth electrode of the light-emitting element.

FIG. 7 is another schematic cross-sectional view of the display device according to the first embodiment.

FIG. 8 is a flowchart showing a method for producing the display device according to the first embodiment.

FIG. 9 is a flowchart showing a method for forming a bank according to the first embodiment.

FIG. 10 illustrates cross-sectional views showing the method for forming the bank according to the first embodiment.

FIG. 11 illustrates other cross-sectional views showing the method for forming the bank according to the first embodiment.

FIG. 12 is an enlarged plan view of a display area of the display device according to a modification of the first embodiment.

FIG. 13 is a schematic cross-sectional view of the display device according to the modification of the first embodiment.

FIG. 14 is a schematic plan view of the display device according to a second embodiment.

FIG. 15 is a schematic cross-sectional view of the display device according to the second embodiment.

FIG. 16 is a schematic plan view of the display device according to a third embodiment.

FIG. 17 is a schematic cross-sectional view of the display device according to the third embodiment.

FIG. 18 is another schematic cross-sectional view of the display device according to the third embodiment.

FIG. 19 is a schematic plan view of the display device according to a fourth embodiment.

FIG. 20 is a schematic cross-sectional view of the display device according to the fourth embodiment.

FIG. 21 is another schematic cross-sectional view of the display device according to the fourth embodiment.

FIG. 22 is a schematic plan view of the display device according to a fifth embodiment.

FIG. 23 is a schematic cross-sectional view of the display device according to the fifth embodiment.

### DESCRIPTION OF EMBODIMENTS

### First Embodiment

Overview of Display Device

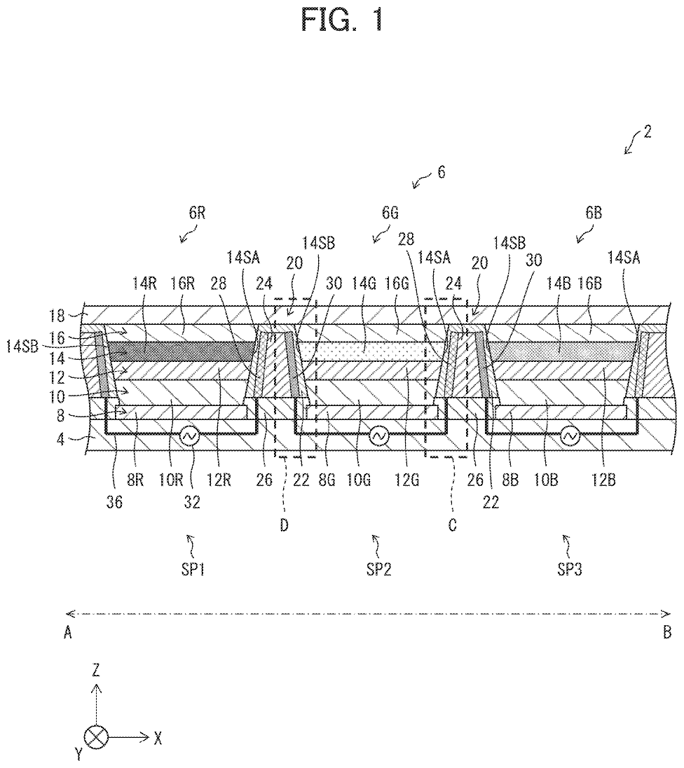

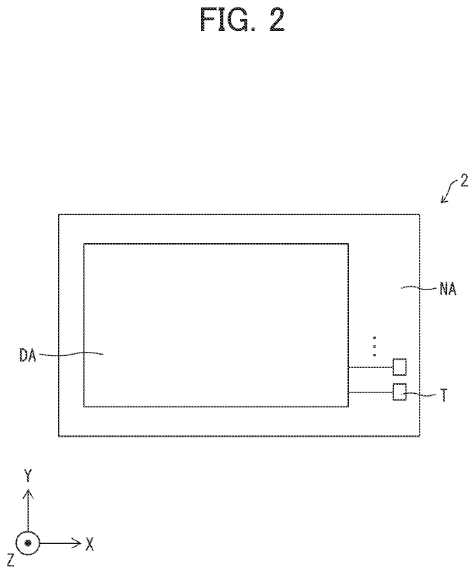

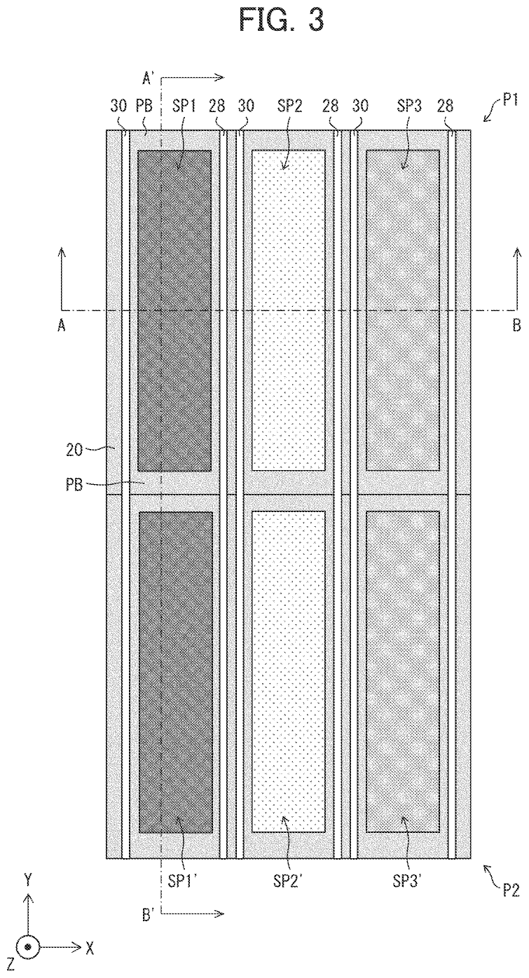

FIG. 2 is a schematic plan view of a display device 2 according to this embodiment. FIG. 3 is an enlarged plan view of a display region of the display device 2 according to this embodiment. The display region will be described later. FIG. 1 is a schematic cross-sectional view of the display device 2 according to this embodiment, taken along line A-B in FIG. 3.

Note that, in Description, an enlarged plan view of the display region of the display device partially illustrates subpixels to be described later in detail and a bank serving as an insulator formed between the subpixels. Moreover, in Description, the enlarged view perspectively illustrates a third electrode and a fourth electrode formed inside the bank.

As illustrated in FIG. 2, the display device 2 according to this embodiment includes: a display region DA that releases light emitted from the light-emitting elements to display an image; and a picture-frame region NA surrounding the display region DA. The light-emitting elements will be described later. The picture-frame region NA includes terminals T formed to receive signals for driving the light-emitting elements of the display device 2.

As illustrated in FIG. 3, the display device 2 according to this embodiment includes a plurality of pixels positioned to overlap with the display region DA in plan view, and including a first pixel P1 and a second pixel P2. Each of the plurality of pixels has a plurality of subpixels. In particular, in this embodiment, the first pixel P1 includes a first subpixel SP1, a second sub-pixel SP2, and a third subpixel SP3. Moreover, the second pixel P1 includes a first subpixel SP1′, a second subpixel SP2′, and a third subpixel SP3′.

As illustrated in FIG. 1, the display device 2 according to this embodiment includes: an array substrate 4; and a light-emitting element layer 6 above the array substrate 4. The array substrate 4 and the light-emitting element layer 6 are positioned to overlap with the display region DA in plan view. In particular, the display device 2 has a structure in which the layers of the light-emitting element layer 6 are stacked on top of another above the array substrate 4 including not-shown thin-film transistors (TFTs). Note that, in Description, the direction from the light-emitting layer 14 toward an anode 8 of the light-emitting element layer 6 is referred to as a “downward direction”, and the direction from the light-emitting layer 14 toward a cathode 18 of the light-emitting element layer 6 is referred to as an “upward direction”. The light-emitting element layer 6 will be described later.

Outline of Light-Emitting Element

The light-emitting element layer 6 includes: a hole injection layer 10; a hole transport layer 12; a light-emitting layer 14; an electron transport layer 16; and a cathode 18 serving as a second electrode, all of which are provided above an anode 8 serving as a first electrode, and stacked on top of another in the stated order from below. In other words, the light-emitting element layer 6 incudes functional layers including: the hole injection layer 10; the hole transport layer 12; the light-emitting layer 14; and the electron transport layer 16, all of which are provided between two electrodes of the anode 8 and the cathode 18. The anode 8 of the light-emitting element layer 6 formed above the array substrate 4 is electrically connected to a TFT of the array substrate 4. Note that the display device 2 is provided with a not-shown sealing layer that seals the light-emitting element layer 6.

In this embodiment, the light-emitting element layer 6 includes a plurality of light-emitting elements. In particular, one light-emitting element is provided for each of the subpixels. In this embodiment, for example, the light-emitting element layer 6 includes, as the light-emitting elements, a light-emitting element 6R in the first subpixel SP1, a light-emitting element 6G in the second subpixel SP2, and a light-emitting element 6B in the third subpixel SP3. The light-emitting element 6R, the light-emitting element 6G, and the light-emitting element 6B may be organic EL elements; namely, OLED elements. That is, the light-emitting element layers 14 of the light-emitting elements 6R, 6G, and 6B are formed of an organic fluorescent material or an organic phosphorescent material. Alternatively, the light-emitting element 6R, the light-emitting element 6G, and the light-emitting element 6B may be QLED elements. That is, the light-emitting layers 14 of the light-emitting elements 6R, 6G, and 6B are formed of a semiconductor nanoparticle material; namely, a quantum dot material. However, in this embodiment, the light-emitting elements 6R, 6G, and 6B are not limited to either OLED elements or QLED elements. As the light-emitting elements 6R, 6G, and 6B, various light-emitting elements can be employed.

Hereinafter, in Description, unless otherwise described, the term “light-emitting element” refers to any one of the light-emitting element 6R, the light-emitting element 6G, and the light-emitting element 6B included in the light-emitting element layer 6.

Here, each of the anode 8, the hole injection layer 10, the hole transport layer 12, the light-emitting layer 14, and the electron transport layer 16 is divided by a bank 20 to be described in detail later. In particular, in this embodiment, the anode 8 is divided by the bank 20 into: an anode 8R for the light-emitting element 6R; an anode 8G for the light-emitting element 6G; and an anode 8B for the light-emitting element 6B. The hole injection layer 10 is divided by the bank into: a hole injection layer 10R for the light-emitting element 6R; a hole injection layer 10G for the light-emitting element 6G; and a hole injection layer 10B for the light-emitting element 6B. The hole transport layer 12 is divided by the bank 20 into: a hole transport layer 12R for the light-emitting element 6R, a hole transport layer 12G for the light-emitting element 6G, and a hole transport layer 12B for the light-emitting element 6B. The light-emitting layer 14 is divided by the bank 20 into: the light-emitting layer 14R, the light-emitting layer 14G; and the light-emitting layer 14B. The electron transport layer 16 is divided by the bank 20 into: an electron transport layer 16R for the light-emitting element 6R, an electron transport layer 16G for the light-emitting element 6G, and an electron transport layer 16B for the light-emitting element 6B.

Note that the cathode 18 is not divided by the bank 20 but formed in common to the plurality of subpixels including the first subpixel SP1, the second subpixel SP2, and the third subpixel SP3.

Hence, in this embodiment, the light-emitting element 6R includes: the anode 8R; the hole injection layer 10R; the hole transport layer 12R; the light-emitting layer 14R; the electron transport layer 16R; and the cathode 18. Moreover, the light-emitting element 6G includes: the anode 8G; the hole injection layer 10G; the hole transport layer 12G; the light-emitting layer 14G; the electron transport layer 16G; and the cathode 18. Furthermore, the light-emitting element 6B includes: the anode 8B; the hole injection layer 10B; the hole transport layer 12B; the light-emitting layer 14B; the electron transport layer 16B; and the cathode 18.

In this embodiment, the light-emitting layer 14R, the light-emitting layer 14G, and the light-emitting layer 14B respectively emit a red light, a green light, and a blue light. In other words, the light-emitting element 6R, the light-emitting element 6G, and the light-emitting element 6B respectively emit a red light, a green light, and a blue light. In still other words, the first subpixel SP1 is colored red, the second subpixel SP2 is colored green, and the third sub-pixel SP3 is colored blue.

Here, the blue light has a center wavelength in a wavelength band of, for example, 400 nm or more and 500 nm or less. Moreover, the green light has a center wavelength in a wavelength band of, for example, more than 500 nm and 600 nm or less. Furthermore, the red light has a center wavelength in a wavelength band of, for example, more than 600 nm and 780 nm or less.

Note that the light-emitting element layer 6 according to this embodiment is not limited to the above configuration, and may further include an additional layer in the functional layers between the anode 8 and the cathode 18. For example, the light-emitting element layer 6 may further include an electron injection layer between the electron transport layer 16 and the cathode 18.

The anode 8 and the cathode 18 are formed of a conductive material, and electrically and respectively connected to the hole injection layer 10 and the electron transport layer 16. Of the anode 8 and the cathode 18, the electrode close to the display surface of the display device 2 is a translucent electrode.

The anode 8 is formed of, for example: an Ag—Pd—Cu alloy; and indium tin oxide (ITO) stacked on the Ag—Pd—Cu alloy. The anode 8 having the above configuration is, for example, a reflective electrode reflective to light emitted from the light-emitting layer 14. Hence, of the light emitted from the light-emitting layer 14, light traveling in the downward direction is reflected off the anode 8.

On the other hand, the cathode 18 is formed of, for example, a translucent Mg—Ag alloy. In other words, the cathode 18 is a transparent electrode transparent to light emitted from the light-emitting layer 14. Hence, of the light emitted from the light-emitting layer 14, light traveling in the upward direction passes through the cathode 18. Thus, the display device 2 can emit the light from the light-emitting layer 14 in the upward direction.

As described above, the display device 2 can direct both of the lights, the light emitted from the light-emitting layer 14 in the upward direction and the light emitted from the light-emitting layer 14 in the downward direction, toward the cathode 18 (in the upward direction). That is, the display device 2 is a top-emission display device.

Moreover, in this embodiment, the cathode 18, which is a translucent electrode, partially reflects the light emitted from the light-emitting layer 14. In this case, a cavity for the light emitted from the light-emitting layer 14 may be formed between the anode 8, which is a reflective electrode, and the cathode 18, which is a translucent electrode. The cavity formed between the anode 8 and the cathode 18 can improve chromaticity of the light emitted from the light-emitting layer 14.

Note that the configurations of the anode 8 and the cathode 18 described above are merely examples, and the anode 8 and the cathode 18 may have other configurations. For example, the anode 8 may be an electrode close to the display surface of the display device 2. In this case, the anode 8 may be a translucent electrode, and the cathode 18 may be a reflective electrode. Thanks to such a feature, the display device 2 can direct both of the lights, the light emitted from the light-emitting layer 14 in the upward direction and the light emitted from the light-emitting layer 14 in the downward direction, toward the anode 8 (in the downward direction). That is, the display device 2 may be a bottom-emission display device.

The light-emitting layer 14 emits light by recombination of holes transported from the anode 8 and electrons transported from the cathode 18. The hole injection layer 10 and the hole transport layer 12 transport the holes from the anode 8 to the light-emitting layer 14. Moreover, the hole transport layer 12 may further have a function to block transportation of the electrons from the cathode 18. The electron transport layer 16 transports the electrons from the cathode 18 to the light-emitting layer 14. Furthermore, the electron transport layer 16 may further have a function to block transportation of the holes from the anode 8.

Note that the display device 2 according to this embodiment includes a light-emitting element including the anode 8 provided toward the array substrate 4. However, the display device 2 may have any given configuration. For example, the light-emitting element layer 6 included in the display device 2 according to this embodiment may include: the cathode 18; the electron transport layer 16; the light-emitting layer 14; the hole transport layer 12; the hole injection layer 10; and the anode 8, all of which are stacked on top of another in the stated order from toward the array substrate 4. In this case, the cathode 18 is a pixel electrode shaped into an island for each of the subpixels, and the anode 8 is a common electrode formed in common to the plurality of subpixels.

Bank, Third Electrode, and Fourth Electrode

Each light-emitting element included in the display device 2 further includes a bank 20. As described above, the bank 20 is a partition wall to divide the functional layers between the anode 8 and the cathode 18 for each subpixel. In other words, the bank 20 is a partition wall formed between the light-emitting elements of the display device 2, and divides the light-emitting elements. In particular, each of the light-emitting element 6R, the light-emitting element 6G, and light-emitting element 6B includes the bank 20 as a first insulator positioned toward a first side surface 14SA of the light-emitting layer 14. Moreover, each of the light-emitting element 6R, the light-emitting element 6G, and the light-emitting element 6B includes another bank 20 as a second insulator positioned toward a second side surface 14SB across from the first side surface 14SA of the light-emitting layer 14.

Each bank 20 illustrated in FIG. 1 includes: a first portion 22, a second portion 24; and a mini-bank 26. The first portion 22 and the second portion 24 are formed on the mini-bank 26 positioned to cover a side surface of, and a vicinity of a peripheral end portion of a top surface of, each anode 8. Note that the second portion 24 and the mini-bank 26 may be formed integrally. Here, the second insulator includes: the first portion 22 as a third portion; and the second portion 24 as a fourth portion.

The first portion 22 is made only of, for example, a first material having an insulating property. The first material may contain an inorganic material. Examples of the inorganic material contained in the first material include SiO₂, diamond, insulating DLC, a ceramic material, and Al₂O₃. Moreover, the first material may contain an organic material. Examples of the organic material contained in the first material include polyimide, polyethylene, polypropylene, vinyl chloride resin, epoxy-based resin, polyester, melamine resin, urea resin, silicone, and polycarbonate. The first material may be at least one selected from the above insulating materials. The first portion 22 containing the first material may have an electrical resistivity of 10⁷ Ω/cm or more. The second portion 24 may be made of the first material. Alternatively, the second portion 24 may contain the first material and a second material different from the first material.

Note that the “insulator” in Description refers to a member containing a material having an electrical resistivity of specifically 10⁷ Ω/cm or more. Moreover, the “insulator” may further be a member containing a material having an electrical resistivity of specifically 10¹⁰ Ω/cm or more. In particular, in Description, as to the bank 20 that is either the first insulator or the second insulator, at least the first portion 22 is made of a material having an electrical resistivity of 10⁷ Ω/cm or more. Furthermore, in Description, as to the bank 20 that is either the first insulator or the second insulator, at least the first portion 22 may further be made of a material having an electrical resistivity of 10¹⁰ Ω/cm or more.

Note that, in the second insulator, the third portion may be made only of, for example, a third material having an insulating property. Moreover, the fourth portion may be made of the third material. Alternatively, the fourth portion may contain the third material and a fourth material different from the third material. The third material may be the same as the first material, and the fourth material may be the same as the second material.

The first portion 22 is formed to surround, and cover, a top surface and a side surface of the second portion 24. Here, the bank 20 includes a third electrode 28 and a fourth electrode 30 between the first portion 22 and the second portion 24. In other words, the bank 20 includes inside the third electrode 28 and the fourth electrode 30.

Moreover, the array substrate 4 further includes a power source 32 electrically connecting to the third electrode 28 through a first wire 34 and to the fourth electrode 30 through a second wire 36. Hence, the display device 2 can apply a voltage from the power source 32 to each of the third electrode 28 and the fourth electrode 30 respectively through the first wire 34 and the second wire 36.

In particular, the power source 32 applies: a first voltage to the third electrode 28 through the first wire 34; and a second voltage to the fourth electrode 30 through the second wire 36. Note that the power source 32 may be an AC power source, and in this case, the first voltage and the second voltage may be AC voltages.

As illustrated in FIG. 1, each third electrode 28 is positioned so that the first portion 22 is sandwiched between the third electrode 28 and the first side surface 14SA of the corresponding light-emitting layer 14. In other words, each third electrode 28 and the first side surface 14SA of the corresponding light-emitting layer 14 face each other across the first portion 22. Moreover, each fourth electrode 30 is positioned so that the first portion 22 is sandwiched between the fourth electrode 30 and the second side surface 14SB of the corresponding light-emitting layer 14. In other words, each fourth electrode 30 and the second side surface 14SB of the corresponding light-emitting layer 14 face each other across the first portion 22.

Furthermore, in this embodiment, side surfaces of the functional layers in each light-emitting elements face the third electrode 28 and the fourth electrode 30 across the first portion 22. In other words, in each light-emitting element, the hole injection layer 10, the hole transport layer 12, the light-emitting layer 14, and the electron transport layer 16 are positioned between the third electrode 28 and the fourth electrode 30. Moreover, because the first portion 22 is formed of the insulating first material, the functional layers of each light-emitting element are electrically insulated from the third electrode 28 and the fourth electrode 30 with the first portion 22.

Hence, a voltage is applied to the third electrode 28 and the fourth electrode 30, so that a difference in potential can be obtained between the third electrode 28 and another electrode, and between the fourth electrode 30 and another electrode. For example, in a case where no voltage is applied to the anode 8, the cathode 18, and the fourth electrode 30 when a voltage is applied to the third electrode 28, a difference in potential is obtained between the third electrode 28 and at least one of the anode 8, the cathode 18, and the fourth electrode 30.

When the difference in potential is obtained at least one of between the third electrode 28 and another electrode or between the fourth electrode 30 and another electrode, an electric field is generated between the electrodes. Hence, each light-emitting element can generate an electric field in a direction different from the stacking direction of the layers.

Advantageous Effects of Third Electrode and Fourth Electrode

Typically, as to a multilayer light-emitting element such as each of the light-emitting elements included in the light-emitting element layer 6, the functional layers formed between the anode 8 and the cathode 18 are layers containing semiconductors. Hence, when the functional layers are in contact with each other, the semiconductors are in contact with each other. Thus, between the functional layers of a multilayer light-emitting element, an interface state could be formed. The interface state might trap carriers injected from each electrode. This trap decreases density of the carriers to be injected into the light-emitting layer, which might lead to a reduction in light emission efficiency.

Each of the light-emitting elements according to this embodiment can apply an electric field in the stacking direction of the light-emitting element, which contributes to transport of the carriers. In addition, each light-emitting element can apply an electric field in a direction different from the stacking direction of the light-emitting element.

Here, when an electric field is applied to the functional layers of each light-emitting element, Fermi levels of the functional layers change. If Fermi levels of two of the functional layers fall below the interface state formed between the two layers, the probability to find carriers in the interface state declines to near 0. In this case, a time constant of the carriers to escape from the interface state exceeds a time constant of the carriers to be trapped in the interface state. Hence, the carriers trapped in the interface state can be released from the interface state.

When the carriers released from the interface state are transported again toward the light-emitting layer 14, the transported carriers can function as carriers that contribute to light emission. Hence, in each light-emitting element according to this embodiment, when a voltage is applied to the third electrode 28 and the fourth electrode 30, the carriers trapped between the functional layers of each light-emitting element can be released, successfully increasing concentration of the carriers that contribute to light emission.

If the layer to which the electric field is applied is an n-type semiconductor layer, a negative voltage is applied to either the third electrode 28 or the fourth electrode 30 with respect to another reference electrode. As a result, the Fermi level of the n-type semiconductor layer falls. Hence, if the light-emitting layer 14 contains an n-type impurity, a negative voltage is applied to either the third electrode 28 or the fourth electrode 30 with respect to either the anode 8 or the cathode 18. As a result, the Fermi level of the light-emitting layer 14 falls, and carriers in the interface state can be released efficiently.

On the other hand, if the layer to which the electric field is applied is a p-type semiconductor layer, a positive voltage is applied to either the third electrode 28 or the fourth electrode 30 with respect to another reference electrode. As a result, the Fermi level of the p-type semiconductor layer falls. Hence, if the light-emitting layer 14 contains a p-type impurity, a positive voltage is applied to either the third electrode 28 or the fourth electrode 30 with respect to either the anode 8 or the cathode 18. As a result, the Fermi level of the light-emitting layer 14 falls, and the carriers in the interface state can be released efficiently.

Moreover, if the electrons are trapped in the interface state, a strong electric field is applied to a functional layer of each light-emitting element. As a result, free electrons in the functional layer are accelerated by the electric field to have high energy. The free electrons could cause an interaction in relation to the electrons trapped in the interface state. Here, if the free electrons are accelerated and the energy of the free electrons rise significantly, the electrons in the interface state, which cause the interaction in relation to the free electron, might be released from the interface state.

Furthermore, an AC electric field is assumed to be applied to the functional layer, and the energy of free electrons is repeatedly increased in a time shorter than the electron-lattice collision time to such an extent that the electrons are released from the interface state. In this case, either the free electrons in the functional layer or the electrons released from the interface state might further cause an interaction with other free electrons in the functional layer or other electrons trapped in the interface state. When such a phenomenon of so-called electron avalanche occurs, other electrons trapped in the interface state could be released more efficiently from the interface state. In this case, each light-emitting element can release the electrons more efficiently from the interface state.

Note that when the electric field to be applied to the functional layer is an AC electric field, compared with the case where a DC electric field is applied to the functional layer, the free electrons in the functional layer are accelerated significantly frequently. Accordingly, the free electrons also cause an interaction significantly frequently with electrons trapped in the interface. Hence, when an AC electric field is applied to the functional layer, the electrons can be released more efficiently from the interface state.

Moreover, when the electric field to be applied to the functional layer is an AC electric field, the AC electric field can cause an interaction highly frequently among the free electrons in the functional layer, as well as between free electrons in the functional layer and electrons trapped in the interface state. Thus, when an AC electric field is applied to the functional layer, compared with a case where a DC electric field is applied to the functional layer, the AC electric field can cause the phenomenon of electron avalanche highly frequently such that the electrons trapped in the interface state can be released more efficiently.

In order to reduce a Fermi level sufficiently and release the carriers efficiently from the interface level, the Fermi level of a functional layer to which an electric field is applied, among the functional layers of each light-emitting element, may be changed higher than the bandgap energy. For this purpose, the functional layer may receive an electric field having energy corresponding to the bandgap. Hence, when an AC voltage is applied to the third electrode 28 or the fourth electrode 30, the AC voltage may have an amplitude twice or more than the magnitude of a voltage generating the electric field having the energy corresponding to the bandgap of the layer to which the electric field is applied.

The functional layers of each light-emitting element are positioned between the third electrode 28; namely, the first insulator and the fourth electrode 30; namely, the second insulator. The third electrode 28 is included in the bank 20 toward the second side surface 14SB. The fourth electrode 30 is included in the bank 20 toward the first side surface 14SA. Hence, when a voltage is applied to both the third electrode 28 and the fourth electrode 30, each light-emitting element can release the carriers more efficiently from the interface state.

When a more uniform electric field is applied to the functional layers, each light-emitting element can release carriers more efficiently from the interface state. Hence, when the first voltage is applied to the third electrode 28 and the second voltage is applied to the fourth electrode 30, the absolute value of the first voltage and the absolute value of the second voltage are preferably the same. Moreover, from the viewpoint of applying a more uniform electric field to the functional layers of each light-emitting element, if the first voltage and the second voltage are AC voltages, the first voltage and the second voltage may be AC voltages having opposite phases.

Note that the third electrode 28 and the fourth electrode 30 may be formed in common to the plurality of subpixels included in different pixels and colored in the same color. For example, as illustrated in FIG. 3, the third electrode 28 and the fourth electrode 30 are formed in common between the subpixels included in the respective first pixel P1 and second pixel P2 and colored in the same color. In other words, the third electrode 28 and the fourth electrode 30 do not have to be individually formed for each subpixel. In this case, in the display device 2, one set of the power source 32, the first wire 34, and the second wire 36 may be provided for each pair of the third electrode 28 and the fourth electrode 30. The set does not have to be provided individually for each sub-pixel.

Detailed Structures of Third Electrode and Fourth Electrode

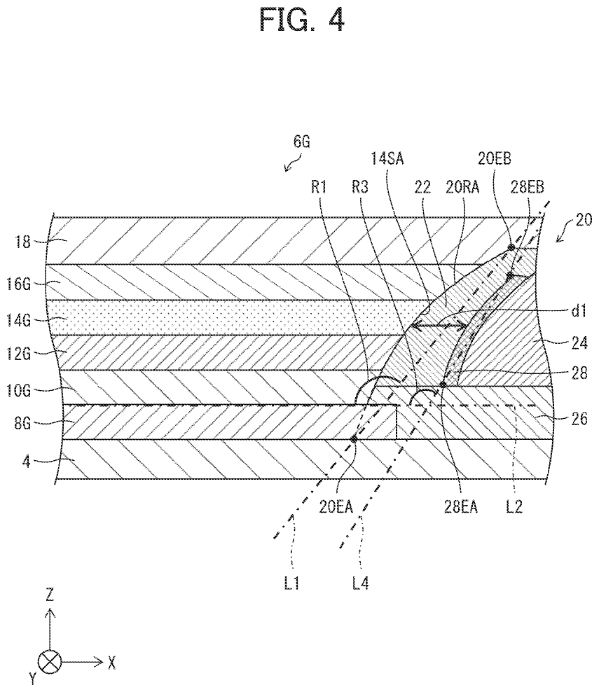

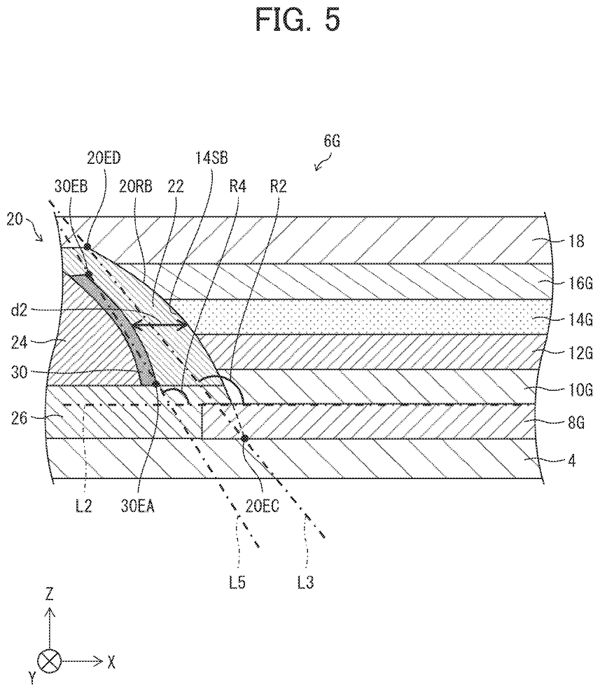

Described below in detail are structures around the third electrode 28 and the fourth electrode 30, with reference to FIGS. 4 and 5. FIGS. 4 and 5 are enlarged cross-sectional views of the display device 2 according to this embodiment. FIG. 4 is an enlarged view of a region C illustrated in FIG. 1, and FIG. 5 is an enlarged view of a region D illustrated in FIG. 1.

As illustrated in FIG. 4, the bank 20 has a first inclined surface 20RA covering the first side surface 14SA of the light-emitting layer 14. The first inclined surface 20RA forms an outer surface of the first portion 22 and the mini-bank 26 toward the first side surface 14SA, and further forms an outer surface of the bank 20 toward the first side surface 14SA.

The first inclined surface 20RA has: an edge 20EA toward the anode 8; and an edge 20EB toward the cathode 18. The edge 20EA is formed at a boundary between the first inclined surface 20RA and a lower surface of the mini-bank 26. The edge 20EB is formed at a boundary between the first inclined surface 20RA and an upper surface of the first portion 22. Here, as illustrated in FIG. 4, the edge 20EA of the first inclined surface 20RA is positioned in contact not with the anode 8 but with the array substrate 4.

Moreover, the third electrode 28 has: an edge 28EA toward the anode 8; and an edge 28EB toward the cathode 18. Here, as illustrated in FIG. 4, the edge 28EA is formed at a boundary between a side surface of the third electrode 28 toward the light-emitting layer 14 and an upper surface of the mini-bank 26, and the edge 28EB is formed at a boundary between a side surface of the third electrode 28 toward the light-emitting layer 14 and an upper surface of the third electrode 28.

Furthermore, as illustrated in FIG. 5, the bank 20 has a second inclined surface 2ORB covering the second side surface 14SB of the light-emitting layer 14. The second inclined surface 2ORB forms an outer surface of the first portion 22 and the mini-bank 26 toward the second side surface 14SB, and further forms an outer surface of the bank 20 toward the second side surface 14 SB.

The second inclined surface 2ORB has: an edge 20EC toward the anode 8; and an edge 20ED toward the cathode 18. The edge 20EC is formed at a boundary between the second inclined surface 2ORB and the lower surface of the mini-bank 26. The edge 20ED is formed at a boundary between the second inclined surface 2ORB and the upper surface of the first portion 22. Here, as illustrated in FIG. 5, the edge 20EC of the second inclined surface 2ORB is positioned in contact not with the anode 8 but with the array substrate 4.

, the fourth electrode 30 has: an edge 30EA toward the anode 8; and an edge 30EB toward the cathode 18. Here, as illustrated in FIG. 4, the edge 30EA is formed at a boundary between a side surface of the fourth electrode 30 toward the light-emitting layer 14 and the upper surface of the mini-bank 26, and the edge 30EB is formed at a boundary between a side surface of the fourth electrode 30 toward the light-emitting layer 14 and an upper surface of the fourth electrode 30.

Note that both the first inclined surface 20RA in FIG. 4 and the second inclined surface 2ORB in FIG. 5 are illustrated as, but not limited to, curved surfaces. For example, both the first inclined surface 20RA and the second inclined surface 2ORB may be flat surfaces. Moreover, both the third electrode 28 and the fourth electrode 30 in FIG. 4 are illustrated as electrodes having curved side surfaces. This is because, as will be described later, the third electrode 28 and the fourth electrode 30 are formed along the side surfaces of the second portion 24 in the bank 20, and the side surfaces of the second portion 24 in FIGS. 4 and 5 are curved. However, other than those examples, the side surface of the second portion 24 may be a flat surface, and furthermore, the side surfaces of the third electrode 28 and the fourth electrode 30 may be flat surfaces.

As illustrated in FIG. 4, a first plane L1 represents a plane passing through the edge 20EA and the edge 20EB. Moreover, a second plane L2 represents a plane in parallel with the upper surface of the anode 8, and the first plane L1 and the second plane L2 form a first angle R1. Furthermore, a third plane L3 represents a plane passing through the edge 20EC and the edge 20ED, and the third plane L3 and the second plane L2 form a second angle R2. In addition, a fourth plane L4 represents a plane passing through the edge EA and the edge EB, and the fourth plane L4 and the second plane L2 form a third angle R3. In addition, a fifth plane L5 represents a plane passing through the edge 30EA and the edge 30EB, and the fifth plane L5 and the second plane L2 form a fourth angle R4.

In this embodiment, the third angle R3 is 90 degrees or larger and the first angle or smaller. The fourth angle R4 is 90 degrees or larger and the second angle or smaller. Alternatively, the third angle R3 and the fourth angle R4 are 90 degrees. Thanks to the above features, distances from the third electrode 28 and the fourth electrode 30 to the functional layers in each light-emitting element are equal in the stacking direction of the layers in the light-emitting element layer 6. Hence, the magnitude of the electric field applied to the functional layers of each light-emitting element is more uniform in the stacking direction of the layers in the light-emitting element layer 6, and consequently, the carriers can be released more efficiently from the interface state.

Moreover, as illustrated in FIG. 4, d1 denotes a distance between the side surface of the third electrode 28 toward the light-emitting layer 14 and the first inclined surface 20RA. As illustrated in FIG. 5, d2 denotes a distance between the side surface of the fourth electrode 30 toward the light-emitting layer 14 and the second inclined surface 2ORB. Here, each of the distance d1 and the distance d2 is the shortest distance on a plane in parallel with the upper surface of the anode 8. In other words, each of the distances d1 and d2 corresponds to a distance between the side surfaces of the functional layers in each light-emitting element and the respective third electrode 28 and fourth electrode 30.

In this embodiment, as illustrated in FIGS. 4 and 5, each of the distance d1 and the distance d2 may vary, depending on the positions of the layers in the light-emitting element layer 6 in the stacking direction. On the other hand, each of the distance d1 and the distance d2 may be constant, depending on the positions of the layers in the light-emitting element layer 6 in the stacking direction. In such a case, the magnitude of the electric field applied to the functional layers of each light-emitting element is more uniform in the stacking direction of the layers in the light-emitting element layer 6, and consequently, the carriers can be released more efficiently from the interface state.

Note that the first portion 22 has a thickness of preferably 10 nm or more and 50 nm or less. Here, the thickness of the first portion 22 indicates an average value of the longest distance and the shortest distance among the distances from the outer surface of the second portion 24, the third electrode 28, or the fourth electrode 30 to the outer surface of the first portion 22 in a direction perpendicular to the stacking direction of each light-emitting element. In other words, the thickness of the first portion 22 indicates the average value of the longest distance and the shortest distance among the distances between the second portion 24, the third electrode 28, or the fourth electrode 30 and the functional layers of the light-emitting element in the direction perpendicular to the stacking direction of the light-emitting element adjacent to the first portion 22.

When the thickness of the first portion 22 is 10 nm or more, electrical insulation can be provided more reliably between the functional layers in each light-emitting element and the third and fourth electrodes 28 and 30. When the thickness of the first portion 22 is 50 nm or more, an electric field sufficient for releasing the carriers from the interface state can be applied more efficiently to the functional layers of each light-emitting element.

Timing of Voltage Application

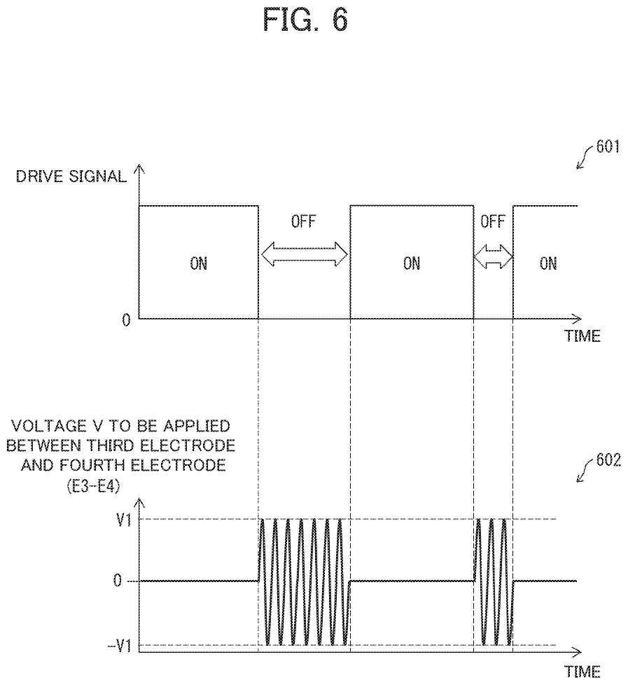

Described below with reference to FIG. 6 are how to drive each light-emitting element, and how to apply a voltage to the third electrode 28 and the fourth electrode 30 of each light-emitting element, in the display device 2 according to this embodiment. FIG. 6 is a timing diagram illustrating application of a drive signal to each light-emitting element according to this embodiment, and application of a voltage between the third electrode 28 and the fourth electrode of the light-emitting element.

A timing diagram 601 in FIG. 6 is of a drive signal for driving each light-emitting element of a pixel included in the display device 2. In the timing diagram 601, the horizontal axis represents time, and the vertical axis represents intensity of the drive signal. A timing diagram 602 in FIG. 6 is of a voltage V to be applied between the third electrode 28 and the fourth electrode 30 included in the light-emitting element. Here, when a potential of the third electrode 28 is E3 and a potential of the fourth electrode 30 is E4, the voltage V is E3-E4. In the timing diagram 602, the horizontal axis represents time, and the vertical axis represents magnitude of the voltage V. In the timing diagram 601, an ON period is a period in which at least one light-emitting element included in a pixel is driven to release light, and an OFF period is a period in which none of the light-emitting elements included in a pixel is not driven.

As shown in the timing diagram 601, a drive signal is applied to the light-emitting element during the ON period in which the light-emitting element releases light. For example, the light-emitting element is driven when a drive signal is applied to each anode 8 while a constant voltage is applied to the cathode 18. On the other hand, a drive signal is not applied to the light-emitting element during the OFF period in which the light-emitting element does not release light.

Here, in the ON period of the light-emitting element illustrated in the timing diagram 601, a voltage is not applied to either the third electrode 28 or the fourth electrode 30 as illustrated in the timing diagram 602; that is, the voltage V is 0. Thus, the light-emitting element can generate only an electric field that contributes to transportation of the carriers to the light-emitting layer 14. Hence, the light-emitting element can reduce influence on the transportation of the carriers to the light-emitting layer 14, thanks to the electric field generated because of the voltage applied to the third electrode 28 and the fourth electrode 30.

Moreover, in the OFF period of the light-emitting element illustrated in the timing diagram 601, a voltage is applied to the third electrode 28 and the fourth electrode 30 as illustrated in the timing diagram 602. In particular, in this embodiment, for example, the voltage V is an AC voltage having an amplitude V1. For example, V1 is a voltage to generate an electric field, which is larger than an electric field corresponding to the bandgap energy of the light-emitting layer 14 in the light-emitting element, between the third electrode 28 and the fourth electrode 30. If the voltage V is an AC voltage, a frequency of the AC voltage may be, for example, a frequency one digit or more higher than a refresh rate of the display device 2.

In this embodiment, a voltage is applied to the third electrode 28 and the fourth electrode when there are no driven light-emitting elements for any of the subpixels included in a pixel. Thus, when a voltage is applied to the third electrode 28 or the fourth electrode 30 included in a light-emitting element adjacent to the light-emitting element to be driven while both of the light-emitting elements are included in the same pixel, such a feature makes it possible to reduce influence of the voltage on transportation of the carriers in the driven light-emitting element.

Moreover, when a light-emitting element included in a pixel is driven for a long time, the OFF period may be provided as appropriate to stop the driving of the light-emitting element, and a voltage may be applied to the third electrode 28 and the fourth electrode 30 during the OFF period. The OFF period may be set, for example, at a frequency of 40 Hz or higher at which flicker is unlikely to be recognized by human.

Cross-Section of Light-Emitting Element without Third Electrode and Fourth Electrode

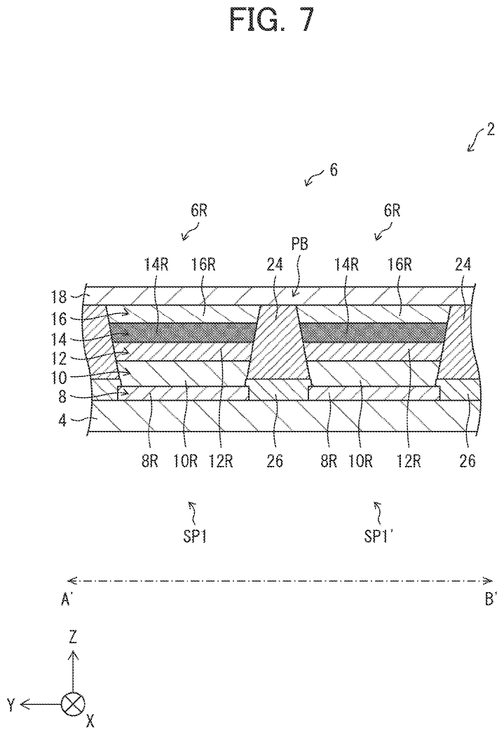

FIG. 7 is another schematic cross-sectional view of the display device 2 according to this embodiment, taken along line A′-B′ in FIG. 3. In this embodiment, a bank PB is formed in place of the bank 20 between adjacent subpixels colored in the same color. For example, as illustrated in FIG. 7, the first subpixel SP1 and the first subpixel SP1′ each include the light-emitting element 6R. The functional layers, included in each of the first subpixel SP1 and the first subpixel SP1′ and provided between the anode 8 and the cathode 18, are separated by the bank PB.

Compared with the bank 20, the bank PB includes only the second portion 24 on the mini-bank 26. In addition, compared with the bank 20, the bank PB includes neither the third electrode 28 nor the fourth electrode 30.

Even if some of the light-emitting elements include the bank PB, as long as each light-emitting element has the bank 20 including either the third electrode 28 or the fourth electrode 30, the carriers can be released from the interface state of each light-emitting element by application of a voltage to the third electrode 28 or the fourth electrode 30. When each light-emitting element includes the bank PB, the third electrode 28 and the fourth electrode 30 do not have to be formed inside any of the banks included in the light-emitting elements. Hence, such a feature simplifies not only the structure but also the forming steps of the light-emitting element.

Outline of Method for Producing Display Device

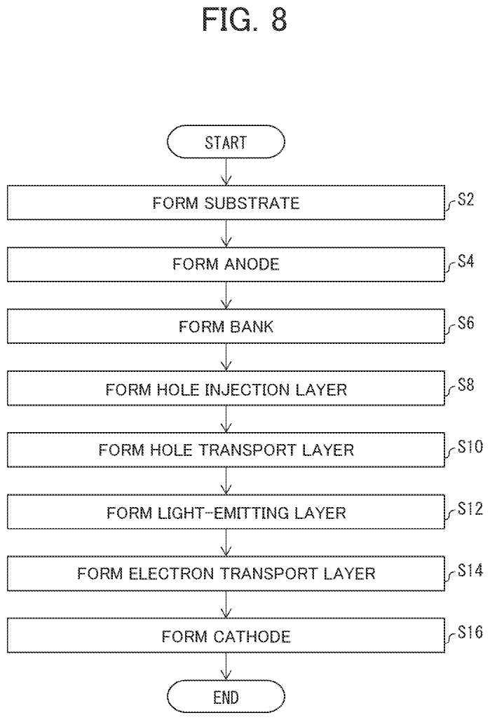

Described next is a method for producing the display device 2 according to this embodiment, with reference to FIG. 8. FIG. 8 is a flowchart showing the method for producing the display device 2 according to this embodiment.

In the method for producing the display device 2 according to this embodiment, first, the array substrate 4 is formed (Step S2). In forming the array substrate 4, a TFT may be formed on a glass substrate in association with the position of the anode 8 formed for each light-emitting element. At Step S2, the power source 32, the first wire 34, and the second wire 36 may be formed inside the array substrate 4.

Next, the anode 8 is formed (Step S4). The anode 8 may be formed of a conductive material deposited by, for example, sputtering. A thin film of the conductive material may be etched and patterned for each subpixel to form the anode 8.

Method for Forming Banks

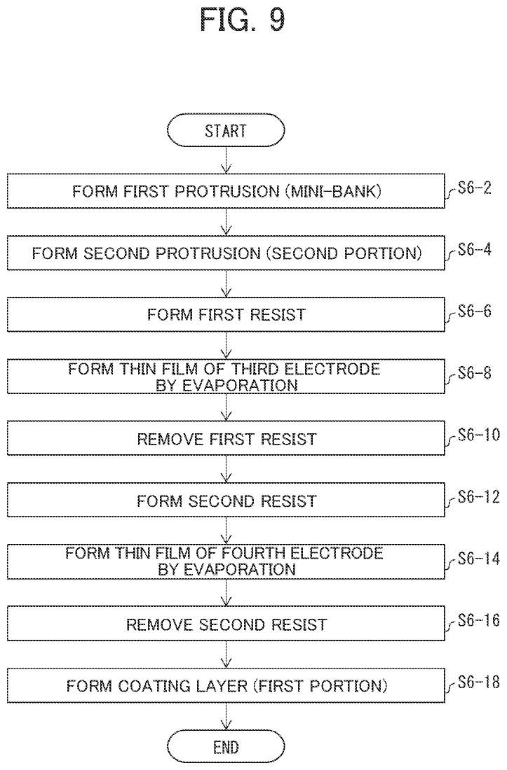

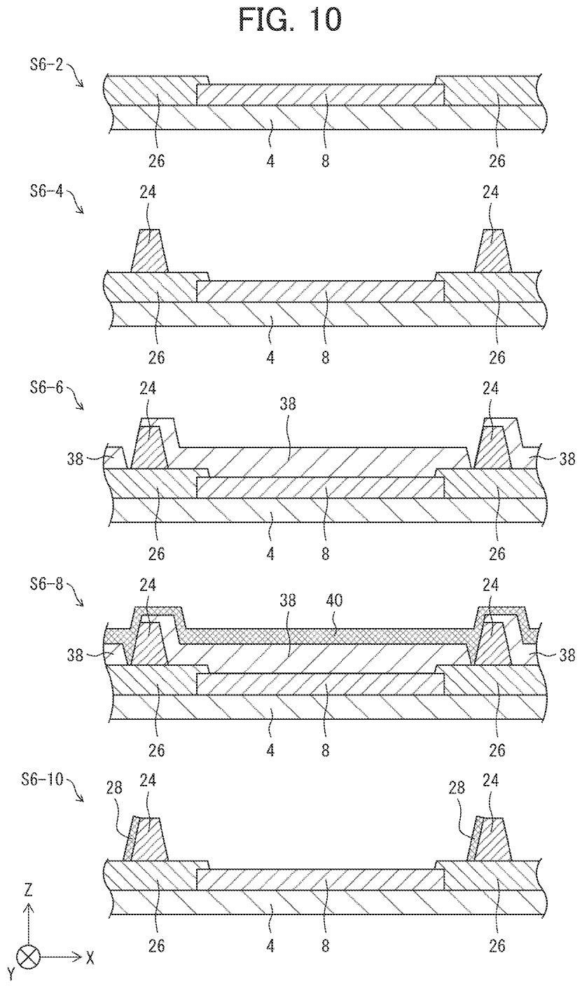

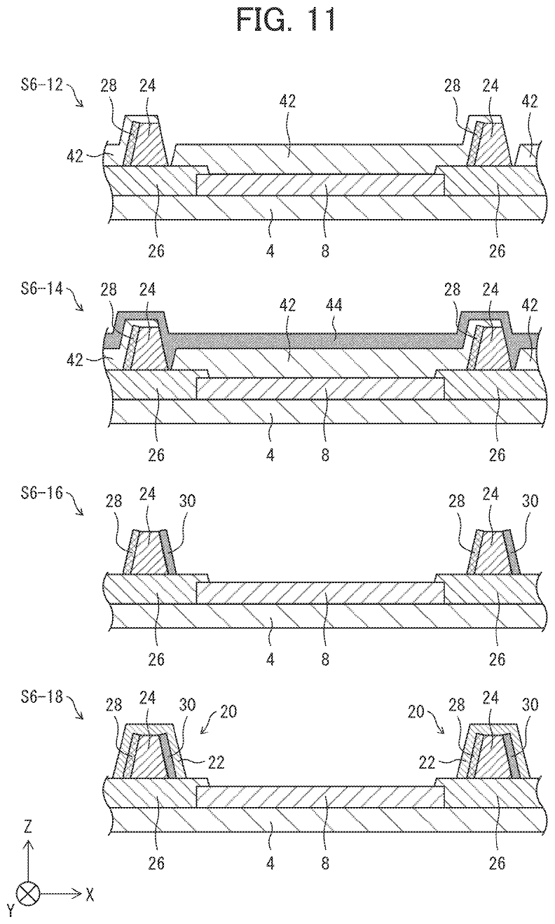

Next, the bank 20 and the bank PB are formed (Step S6). Here, a method for forming the bank 20 will be described in more detail with reference to FIGS. 9 to 11. FIG. 9 is a flowchart showing the method for forming the bank 20 according to this embodiment. FIGS. 10 and 11 are cross-sectional views illustrating the steps of the method for forming the bank 20 according to this embodiment. Note that FIGS. 10 and 11 are enlarged cross-sectional views of a sub-pixel included in the display device 2, illustrating a cross-section of the subpixel in a position in which the bank 20 is formed.

At a step of forming the bank 20, first, a first protrusion forming step is carried out to form the mini-bank 26 that serves as a first protrusion (Step S6-2). The mini-bank 26 may be formed of a material mixture containing a resin material such as polyimide resin and a photosensitive material. The material mixture may be applied and patterned by photolithography, and provided with an opening positioned to overlap with each anode 8 in plan view. Thus, the mini-bank 26 may be formed. At the step of forming the mini-bank 26, contact holes may be formed in the mini-bank 26 for forming the first wire 34 and the second wire 36.

Next, a second protrusion forming step is carried out to form the second portion 24 that serves as a second protrusion (S6-4). The second portion 24 may be formed by the same technique as the mini-bank 26 is, except for the position and the shape in which the second portion 24 is formed. Moreover, when the second portion 24 is formed, a step of forming the bank PB may end.

In particular, the second portion 24 is formed on an upper surface of the mini-bank 26. Moreover, the second portion 24 included in the bank 20 is formed smaller than the mini-bank 26 in plan view of the array substrate 4. Note that the mini-bank 26 and the second portion 24 may be formed at a time at the same step by such a technique as photolithography using a halftone mask.

Next, a step of forming the third electrode 28 is carried out. At the step of forming the third electrode 28, first, a first resist 38 is formed (Step S6-6). In forming the first resist 38, for example, a material containing a photosensitive resin is applied to form a layer. After that, the layer is patterned by photolithography so that the first resist 38 is obtained. The first resist 38 is formed in a position other than one side surface, of the second portion 24, on which the third electrode 28 is formed. In particular, the first resist 38 is formed in a position to cover all the side surfaces of the mini-bank 26.

Next, the conductive layer 40 containing the material of the third electrode 28 is deposited on a side surface of the second portion 24, and on an upper surface and a side surface of the first resist 38 (Step S6-8). The conductive layer 40 may be deposited of, for example, the material of the conductive layer 40 by evaporation, sputtering, or the CVD.

Because the first resist 38 is formed in a position other than one side surface of the second portion 24, the conductive layer 40 is formed in a position to cover the one side surface of the second portion 24. Moreover, because the first resist 38 is formed in a position to cover all the side surfaces of the mini-bank 26, the mini-bank 26 has no side surface to be directly covered with the conductive layer 40. Note that the conductive layer 40 may be formed also inside the contact hole formed in the mini-bank 26. Thanks to such a feature, the first wire 34 and the conductive layer 40 may be electrically connected together.

Next, the first resist 38 is removed with an appropriate solvent including, for example, acetone (Step S6-10). With the removal of the first resist 38, the conductive layer 40 formed on the upper surface and the side surface of the first resist 38 is removed. Hence, the only remaining conductive layer 40 is the one formed on the side surface of the second portion 24, and the remaining conductive layer 40 forms the third electrode 28. Thus, the step of forming the third electrode 28 is completed.

Next, a step of forming the fourth electrode 30 is carried out. At the step of forming the fourth electrode 30, first, a second resist 42 is formed (Step S6-12). In forming the second resist 42, for example, the same material as the material of the first resist 38 is applied to form a layer. After that, the layer is patterned by photolithography so that the second resist 42 is obtained. The second resist 42 is formed in a position other than a side surface different from the one side surface, of the second portion 24, on which the third electrode 28 is formed. In particular, the second resist 42 is formed in a position to cover all the side surfaces of the mini-bank 26.

Next, the conductive layer 44 containing the material of the fourth electrode 30 is formed on a side surface of the second portion 24, and on an upper surface and a side surface of the second resist 42 (Step S6-14). The conductive layer 44 may be deposited by the same technique as the technique of depositing the conductive layer 40.

The second resist 42 is formed in a position other than a side surface different from the one side surface, of the second portion 24, on which the third electrode 28 is formed. Hence, the conductive layer 44 is formed in a position to cover the side surface. Moreover, because the second resist 42 is formed in a position to cover all the side surfaces of the mini-bank 26, the mini-bank 26 has no side surface to be directly covered with the conductive layer 44. Note that the conductive layer 44 may be formed also inside the contact hole formed in the mini-bank 26. Thanks to such a feature, the second wire 36 and the conductive layer 44 may be electrically connected together.

Next, the second resist 42 is removed with an appropriate solvent including, for example, acetone (Step S6-16). With the removal of the second resist 42, the conductive layer 44 formed on the upper surface and the side surface of the second resist 42 is removed. Hence, the only remaining conductive layer 44 is the one formed on the side surface different from the one side surface, of the second portion 24, on which the third electrode 28 is formed. The remaining conductive layer 44 forms the fourth electrode 30 Thus, the step of forming the fourth electrode 30 is completed.

Finally, a coating layer forming step is carried out to form the first portion 22 that serves as a coating layer (Step S6-18). The first portion 22 may be formed by the same technique as the second portion 24 and the mini-bank 26 are, except for the position and the shape in which the first portion 22 is formed. In particular, the first portion 22 is formed in a position to cover the second portion 24, the third electrode 28, and the fourth electrode 30. Thus, the formation of the bank 20 is completed.

Note that, if the third electrode 28 and the fourth electrode 30 are made of the same material, the third electrode 28 and the fourth electrode 30 may be formed at a time at the same step. For example, at Step S6-6, the first resist 38 is formed in a position other than opposing side surfaces of the second portions 24, and then Steps S6-8 and S6-10 are sequentially carried out to form the third electrode 28 and the fourth electrode 30 at a time. In this case, Steps S6-12 to S6-16 may be omitted.

Method for Forming Light-Emitting Element after Bank Forming Step

Following the step of forming the bank 20, the hole injection layer 10 and the hole transport layer 12 are sequentially formed (Steps S8 and S10). The hole injection layer 10 and the hole transport layer 12 may be formed, for example, by vacuum evaporation or sputtering of a hole injecting material and a hole transporting material. Alternatively, the hole injection layer 10 and the hole transport layer 12 may be formed by coating with a colloidal solution.

Next, the light-emitting layer 14 is formed (Step S12). When the light-emitting layer 14 contains an organic light-emitting material, for example, the light-emitting layer 14 may be formed by such a technique as vacuum evaporation. When some of the subpixels included in the display device 2 have different colors, the light-emitting layer 14 may be formed by repetition of vacuum evaporation for each of the colors of the subpixels, using a metal mask having openings positioned to correspond to the some subpixels.

In addition, for example, when the light-emitting layer 14 contains a quantum dot light-emitting material, the light-emitting layer 14 may be formed by coating with a colloidal solution containing the quantum dot light-emitting material, or by electrodeposition of the quantum dot material. When some of the subpixels included in the display device 2 have different colors, the light-emitting layer 14 may be formed by repetition, for each of the colors of the subpixels, of coating with a light-emitting material and lifting-off of the light-emitting material using a photoresist.

Next, the electron transport layer 16 is formed (Step S14). The electron transport layer 16 may be formed, for example, by vacuum evaporation or sputtering of an electron transporting material. Alternatively, the electron transport layer may be formed by coating with a colloidal solution. Next, the cathode 18 is formed (Step S16). The cathode 18 may be formed of a conductive material. The conductive material may be deposited by, for example, sputtering over a plurality of pixels. This is how the display device 2 according to this embodiment is produced.

### Summary of First Embodiment

The display device 2 according to this embodiment includes, for each of the subpixels, a light-emitting element capable of releasing the carriers from an interface state formed between the functional layers provided between the anode 8 and the cathode 18. The carriers are released when a voltage is applied to the third electrode 28 or the fourth electrode 30. Hence, the display device 2 includes a plurality of light-emitting elements with improved light emission efficiency. Such a feature saves power consumption of, or increases the life of, the display device 2.

In the display device 2 according to this embodiment, the first subpixel SP1 includes the light-emitting element 6R that emits a red light, the second subpixel SP2 includes the light-emitting element 6G that emits a green light, and the third subpixel SP3 includes the light-emitting element 6B that emits a blue light. For this reason, the first subpixel SP1, the second subpixel SP2, and the third subpixel SP3 have different colors. Thanks to such a feature, the display device 2 according to this embodiment can present three primary colors, and, in particular, full colors.

Moreover, in this embodiment, the third electrode 28 of the first subpixel SP1 and the fourth electrode 30 of the second subpixel SP2 are positioned between the first subpixel SP1 and the second subpixel SP2. Furthermore, in this embodiment, the third electrode 28 of the second subpixel SP2 and the fourth electrode 30 of the third subpixel SP3 are positioned between the second subpixel SP2 and the third subpixel SP3. In other words, the display device 2 according to this embodiment includes the third electrode 28 and the fourth electrode 30 between adjacent subpixels having different colors.

In this embodiment, as illustrated in FIG. 3, each of the subpixels of the display device 2 may be shaped so that, the size in the direction in which the subpixels having different colors are adjacent to each other may be either smaller or larger than the size in the direction in which the subpixels having the same color are adjacent to each other. In this case, the distance between the third electrode 28 and the fourth electrode 30 included in the same light-emitting element is shorter, so that a higher electric field can be applied to the functional layers of the light-emitting element.

Modification

Modification of Bank

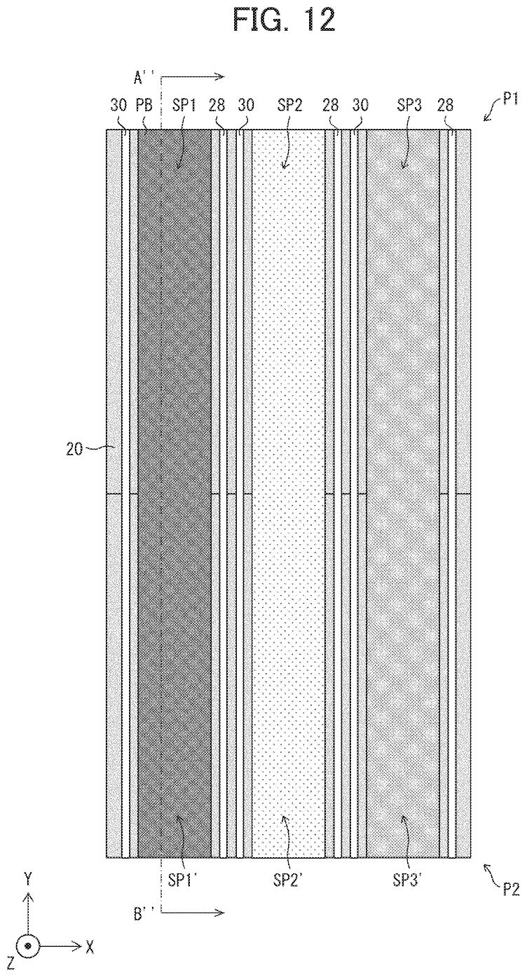

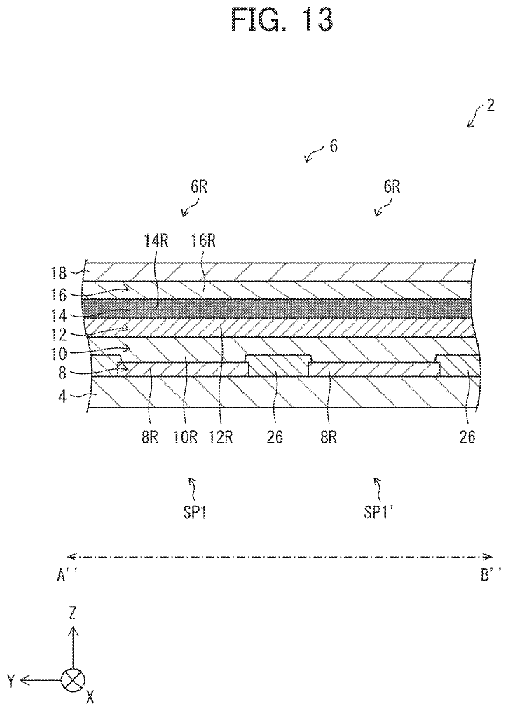

FIG. 12 is an enlarged plan view of a display region of the display device 2 according to a modification of this embodiment. FIG. 13 is a schematic cross-sectional view of the display device 2 according to the modification of this embodiment, taken along line A″-B″ in FIG. 12.

The display device 2 according to the modification of this embodiment is the same in configuration as the display device 2 according to this embodiment, except that, instead of the bank PB, only the mini-bank 26 is formed between the adjacent subpixels having the same color.

Hence, in the display device 2 according to the modification of this embodiment, as illustrated in FIG. 13, the functional layers of the light-emitting elements are formed in common to the subpixels having the same color. Note that the anode 8 is shaped into an island for each subpixel. Hence, when each anode 8 is driven individually, the light-emitting element included in each subpixel can be controlled individually.

Also, in the modification of this embodiment, the bank 20 is formed between adjacent subpixels having different colors. Thus, in each of the light-emitting elements according to the modification of this embodiment, the carriers trapped in an interface state between the functional layers can be released, so that the light-emitting element can improve light emission efficiency. Moreover, in the modification of this embodiment, the functional layers of each light-emitting element are formed in common to subpixels having the same color, and fewer positions are required to form the second portion. Hence, in the modification of this embodiment, not only the structure but also the forming steps of each light-emitting element are simplified.

### Second Embodiment

Common Electrode

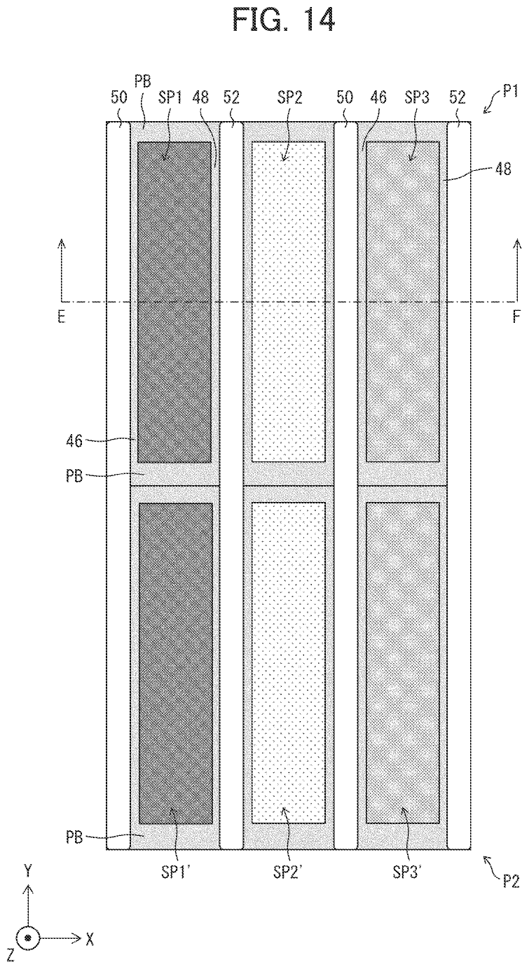

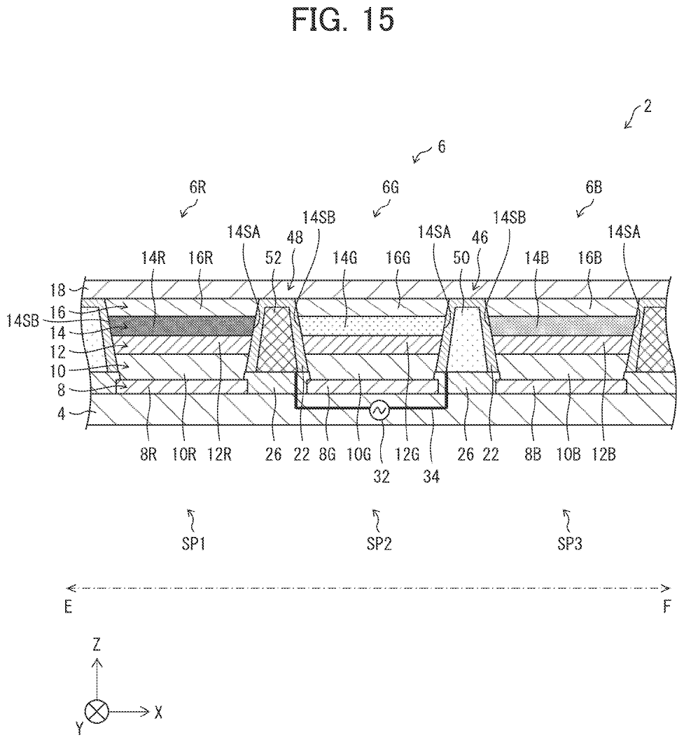

FIG. 14 is an enlarged plan view of a display region of the display device 2 according to this embodiment. FIG. 15 is a schematic cross-sectional view of the display device 2 according to this embodiment, taken along line E-F in FIG. 14.

Compared with the display device 2 according to the previous embodiment, the display device 2 according to this embodiment includes, instead of the bank 20, either a bank 46 or a bank 48 formed between adjacent subpixels having different colors. In other words, compared with each light-emitting element according to the previous embodiment, each light-emitting element according to this embodiment includes, instead of the bank 20, the bank 46 and the bank 48 as the first insulator and the second insulator.

Here, for example, the light-emitting element 6G formed in the second subpixel SP2 includes the bank 46 provided toward the first side surface 14SA of the light-emitting layer 14G. Moreover, the light-emitting element 6G includes the bank 48 toward the second side surface 14SB of the light-emitting layer 14G. On the other hand, the light-emitting element 6R formed in the first sub-pixel SP1 includes the bank 48 toward the first side surface 14SA of the light-emitting layer 14R, and the light-emitting element 6B formed in the third subpixel SP3 includes the bank 48 toward the first side surface 14SA of the light-emitting layer 14B. Moreover, the light-emitting element 6R includes the bank 46 toward the second side surface 14SB of the light-emitting layer 14R, and the light-emitting element 6B includes the bank 46 toward the second side surface 14SB of the light-emitting layer 14B.

The bank 46 includes, on the mini-bank 26: a third electrode 50; and the first portion 22 covering a side surface and a periphery of the third electrode 50. On the other hand, the bank 48 includes, on the mini-bank 26: a fourth electrode 52; and the first portion 22 covering a side surface and a periphery of the fourth electrode 52. The third electrode 50 and the fourth electrode 52 are electrically connected to the power source 32 respectively through the first wire 34 and the second wire 36.

Except for the above configuration, the display device 2 according to this embodiment may be the same in configuration as the display device 2 according to the previous embodiment.

Except for Step S6, the display device 2 according to this embodiment can be produced by the same method as the method for producing the display device 2 according to the previous embodiment. At Step S6 according to this embodiment, for example, Step S6-4 described above is omitted, and at Step S6-6, the first resist 38 is formed in a position except for only a portion of the upper surface of the mini-bank 26. Next, Steps S6-8 and S6-10 are sequentially carried out to form the third electrode 50 on the mini-bank 26. The fourth electrode 52 can be formed by the same technique as the third electrode 50 is, except for the position in which the fourth electrode 52 is formed. Otherwise, Step S6 according to this embodiment can be carried out by the same technique as Step S6 according to the previous embodiment is.

The light-emitting element 6G includes: the third electrode 50 toward the first side surface 14SA through the first portion 22 of the bank 46; and the fourth electrode 52 toward the second side surface 14SB through the first portion 22 of the bank 48. Moreover, each of the light-emitting element 6R and the light-emitting element 6B includes: the fourth electrode 52 toward the first side surface 14SA through the first portion 22 of the bank 48; and the third electrode 50 toward the second side surface 14SB through the first portion 22 of the bank 46. Furthermore, the power source 32 can apply a voltage to each of the third electrode 50 and the fourth electrode 52 through the first wire 34 and the second wire 36.

Hence, when a voltage is applied to at least one of the third electrode 50 and the fourth electrode 52, each light-emitting element according to this embodiment can generate an electric field between the at least one electrode and another electrode. Thus, in each light-emitting element according to the present embodiment, the third electrode 50 and the fourth electrode 52 can release the carriers trapped in an interface state between the functional layers, so that the light-emitting element can improve light emission efficiency.

Moreover, the bank 46 includes only the third electrode 50 as an electrode, and the bank 48 has only the fourth electrode 52 as an electrode. Furthermore, in the display device 2 according to this embodiment, a light-emitting element and another light-emitting element adjacent to the light-emitting element share either the third electrode 50 or the fourth electrode 52.

For example, the third electrode 50 of the bank 46 illustrated in FIG. 15 functions as a third electrode of the light emitting element 6G in the second subpixel SP2, and also functions as a fourth electrode of the light-emitting element 6B in the third subpixel SP3. Moreover, the fourth electrode 52 of the bank 48 illustrated in FIG. 15 functions as a third electrode of the light-emitting element 6R in the first subpixel SP1, and also functions as a fourth electrode of the light-emitting element 6G in the second subpixel SP2.

Hence, compared with the bank 20 including both the third electrode 28 and the fourth electrode 30, the bank 46 and the bank 48 include only one of the third electrode 50 or the fourth electrode 52 as an electrode. so that not only the structure but also the forming steps of the banks 46 and 48 are simplified. Moreover, between adjacent light-emitting elements, application of a voltage to the third electrode of one of the light-emitting elements can be interpreted as application of a voltage to the fourth electrode of another light-emitting element adjacent to the one light-emitting element. Such a feature of the display device 2 according to the present embodiment can reduce the number of the power sources 32, the first wires 34, and the second wires 36 to be used for applying a voltage to the third electrodes 50 and the fourth electrodes 52.

### Third Embodiment

Omission of Some Electrodes

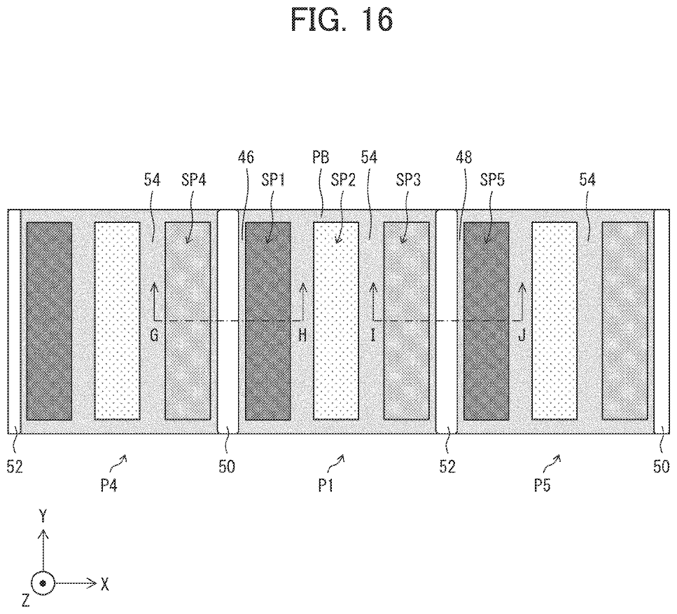

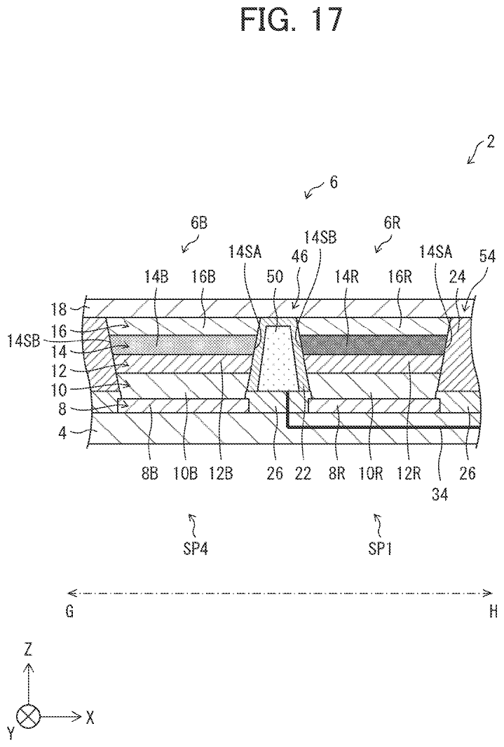

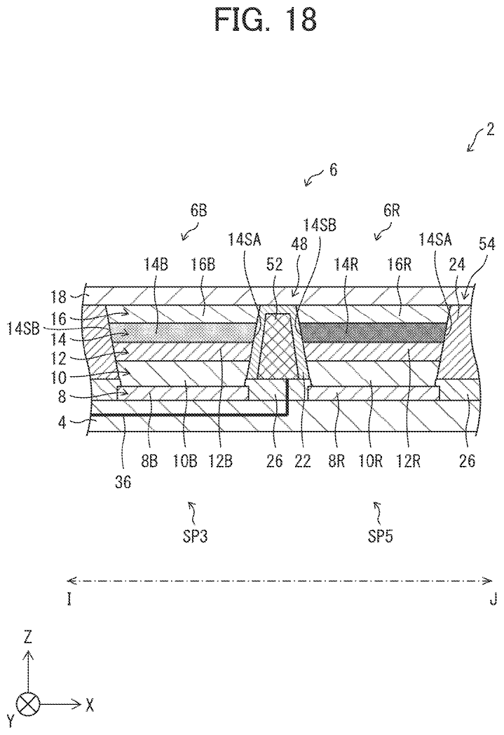

FIG. 16 is an enlarged plan view of a display region of the display device 2 according to this embodiment. FIG. 17 is a schematic cross-sectional view of the display device 2 according to this embodiment, taken along line G-H in FIG. 16. FIG. 18 is another schematic cross-sectional view of the display device 2 according to this embodiment, taken along line I-J in FIG. 16.

Compared with the display device 2 according to the previous embodiment, the display device 2 according to this embodiment includes the bank 46 or the bank 48 between adjacent subpixels included in different pixels and having different colors. Moreover, compared with the display device 2 according to the previous embodiment, the display device 2 according to this embodiment includes a bank 54 between adjacent subpixels included in the same pixel.

For example, as illustrated in FIGS. 16 and 17, the display device 2 includes a fourth pixel P4 adjacent to the first pixel P1. The fourth pixel P4 includes a fourth subpixel SP4 as a subpixel adjacent to the first subpixel SP1 of the first pixel P1. The fourth subpixel SP4 includes the light-emitting element 6B. Here, the bank 46 is formed between the first subpixel SP1 and the fourth subpixel SP4. Hence, the second side surface 14SB of the light-emitting element 6R in the first subpixel SP1 and the first side surface 14SA of the light-emitting element 6B in the fourth subpixel SP4 face the third electrode 50 across the first portion 22.

Moreover, as illustrated in FIGS. 16 and 18, the display device 2 includes a fifth pixel P5; that is, another pixel adjacent to the first pixel P1. The fifth pixel P5 includes a fifth sub-pixel SP5 as a subpixel adjacent to the third subpixel SP3 of the first pixel P1. The fifth subpixel SP5 includes the light-emitting element 6R. Here, the bank 48 is formed between the third sub-pixel SP3 and the fifth subpixel SP5. Hence, the first side surface 14SA of the light-emitting element 6B in the third subpixel SP3 and the second side surface 14SB of the light-emitting element 6R in the fifth subpixel SP5 face the fourth electrode 52 across the first portion 22.

Also, in this embodiment, the third electrode 50 and the fourth electrode 52 are electrically connected to the not-shown power source 32 respectively through the first wire 34 and the second wire 36. Hence, also in this embodiment, the power source 32 can apply a first voltage to the third electrode 50 through the first wire 34 and a second voltage to the fourth electrode 52 through the second wire 36.

As illustrated in FIG. 16, because the bank 54 is formed between the first subpixel SP1 and the second subpixel SP2 included in the first pixel P1, and between the second subpixel SP2 and the third subpixel SP3 included in the first pixel P1, neither the third electrode 50 nor the fourth electrode 52 is formed. However, the light-emitting element 6G of the second sub-pixel SP2 and the light-emitting element 6B of the third subpixel SP3 face the third electrode 50 across the light-emitting element 6R of the first subpixel SP1. Moreover, the light-emitting element 6R of the first subpixel SP1 and the light-emitting element 6G of the second subpixel SP2 face the fourth electrode 52 across the light-emitting element 6B of the third subpixel SP3.

In other words, the light-emitting element 6R of the first subpixel SP1, the light-emitting element 6G of the second subpixel SP2, and the light-emitting element 6B of the third sub-pixel SP3 include the third electrode 50 that serves as the third electrode between the first subpixel SP1 and the fourth subpixel SP4. Moreover, the light-emitting element 6R of the first subpixel SP1, the light-emitting element 6G of the second subpixel SP2, and the light-emitting element 6B of the third subpixel SP3 include the fourth electrode 52 that serves as the fourth electrode between the third subpixel SP3 and the fifth subpixel SP5.

Except for the above configuration, the display device 2 according to this embodiment may be the same in configuration as the display device 2 according to the previous embodiment.

Except for Step S6, the display device 2 according to this embodiment can be produced by the same method as the method for producing the display device 2 according to the previous embodiment. At Step S6 according to this embodiment, for example, at Step S6-6, the first resist 38 is formed on the upper surface of the mini-bank 26 between adjacent light-emitting elements included in the same pixel. Next, Steps S6-8 and S6-10 are sequentially carried out, and the third electrode 50 can be formed only on some of the mini-banks 26 between adjacent light-emitting elements included in different pixels. The fourth electrode 52 can be formed by the same technique as the third electrode 50 is, except for the position in which the fourth electrode 52 is formed. Otherwise, Step S6 according to this embodiment can be carried out by the same technique as Step S6 according to the previous embodiment is.

Each of the light-emitting element 6R of the first subpixel SP1, the light-emitting element 6G of the second subpixel SP2, and the light-emitting element 6B of the third sub-pixel SP3 according to the present embodiment includes the same third electrode 50 and fourth electrode 52. Hence, in this embodiment, when a voltage is applied to at least one of the third electrode 50 or the fourth electrode 52, electric fields can be simultaneously generated for the respective light-emitting element 6R, light-emitting element 6G, and light-emitting element 6B included in the same first pixel P1.

Hence, when a voltage is applied to at least one of the third electrode 50 and the fourth electrode 52, each light-emitting element according to this embodiment can generate an electric field between the at least one electrode and another electrode. Thus, in each light-emitting element according to the present embodiment, the third electrode 50 and the fourth electrode 52 can release the carriers trapped in an interface state between the functional layers, so that the light-emitting element can improve light emission efficiency.

Moreover, the display device 2 according to this embodiment applies a voltage to at least one of the third electrode 50 and the fourth electrode 52 in a pair, for each of a plurality of light-emitting elements included in the same pixel. Hence, an electric field can be applied to the functional layers of each light-emitting element. In other words, neither the third electrode 50 nor the fourth electrode 52 is formed between adjacent light-emitting elements included in the same pixel. Such a feature of the display device 2 according to the present embodiment can reduce the number of, and simplify the forming steps of, the third electrodes 50 and the fourth electrodes 52.

Note that the banks 46 and 48 according to this embodiment may be the same in configuration as the bank 20. In other words, the banks 46 and 48 may have a structure including both the third electrode and the fourth electrode. In this case, the bank 46 may include: a third electrode of the light-emitting element 6B in the fourth subpixel SP4; and a fourth electrode of the light-emitting element 6R in the first subpixel SP1, the light-emitting element 6G in the second subpixel SP2, and the light-emitting element 6B in the third subpixel SP3. Alternatively, the bank 48 may include: a third electrode of the light-emitting element 6R in the first sub-pixel SP1, the light-emitting element 6G in the second subpixel SP2, and the light-emitting element 6B in the third subpixel SP3; and a fourth electrode of the light-emitting element 6R in the fifth subpixel SP5.

### Fourth Embodiment

Change of Direction in Forming Electrode

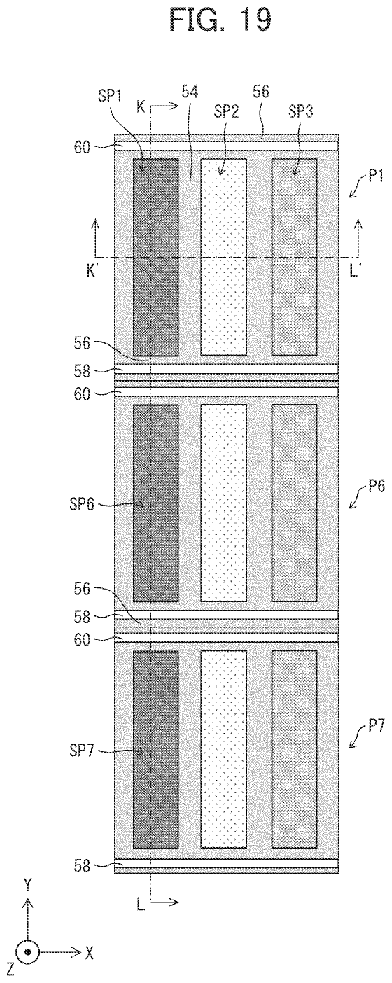

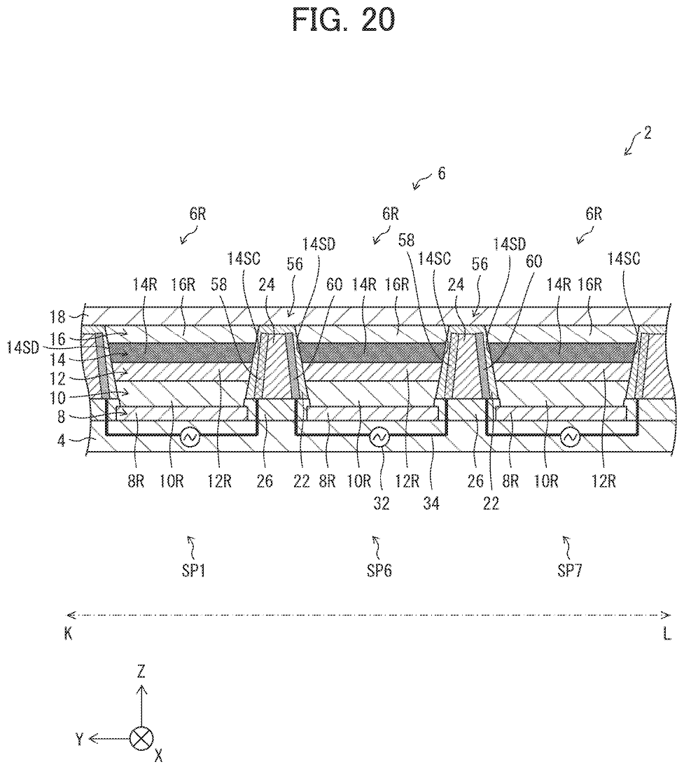

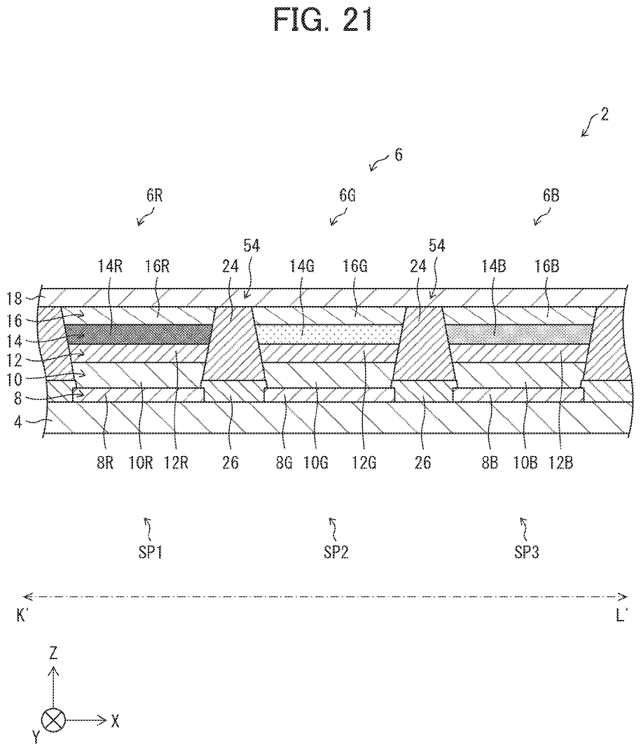

FIG. 19 is an enlarged plan view of a display region of the display device 2 according to this embodiment. FIG. 20 is a schematic cross-sectional view of the display device 2 according to this embodiment, taken along line K-L in FIG. 19. FIG. 21 is another schematic cross-sectional view of the display device 2 according to this embodiment, taken along line K′-L′ in FIG. 19.

Compared with the display device 2 according to the first embodiment, the display device 2 according to this embodiment includes, instead of the bank PB, a bank 56 between adjacent subpixels included in different pixels and having the same color. Moreover, compared with the display device 2 according to the first embodiment, the display device 2 according to this embodiment includes the bank 54 between subpixels having different colors.

For example, as illustrated in FIGS. 19 and 20, the display device 2 includes a sixth pixel P6 adjacent to the first pixel P1. The sixth pixel P6 includes a sixth subpixel SP6 as a sub-pixel adjacent to the first subpixel SP1 of the first pixel P1. The sixth subpixel SP6 includes the light-emitting element 6R. Moreover, the display device 2 includes a seventh pixel P7 adjacent to the sixth pixel P6. The seventh pixel P7 includes a seventh subpixel SP7 as a subpixel adjacent to the sixth subpixel SP6 of the sixth pixel P6. The seventh subpixel SP7 includes the light-emitting element 6R.

Here, the bank 56 is formed between the first subpixel SP1 and the sixth subpixel SP6 and between the sixth subpixel SP6 and the seventh subpixel SP7. The bank 56 is the same in configuration as the bank 20, except for including a third electrode 58 instead of the third electrode 28, and a fourth electrode 60 instead of the fourth electrode 30.

As illustrated in FIGS. 19 and 20, each of the first subpixel SP1, the sixth subpixel SP6, and the seventh subpixel SP7 includes the light-emitting element 6R, and the light-emitting layer 14R of each light-emitting element 6R has a first side surface 14SC facing the third electrode 58 across the first portion 22. Moreover, each of the first subpixel SP1, the sixth subpixel SP6, and the seventh subpixel SP7 includes the light-emitting element 6R, and the light-emitting layer 14R of each light-emitting element 6R has a second side surface 14SD facing the fourth electrode 60 across the first portion 22. The third electrode 58 and the fourth electrode 60 are electrically connected to the power source 32 respectively through the first wire 34 and the second wire 36.

Each of the third electrode 58 and the fourth electrode 60 is formed in common to a plurality of subpixels in a direction in which subpixels having different colors are adjacent to each other. For example, as illustrated in FIG. 19, each of the third electrode 58 and the fourth electrode 60 is formed in common to the first subpixel SP1, the second subpixel SP2, and the third sub-pixel SP3 of the first pixel P1.

Except for the above feature, the third electrode 58 and the fourth electrode 60 are respectively the same in configuration as the third electrode 28 and the fourth electrode 30.

Moreover, as illustrated in FIGS. 19 and 21, the display device 2 includes the bank 54 between the first subpixel SP1 and the second subpixel SP2, and between the second sub-pixel SP2 and the third subpixel SP3. The bank 54 according to this embodiment is the same in configuration as the bank 54 described above except for the position in which the bank 54 is formed.

Except for the above configuration, the display device 2 according to this embodiment may be the same in configuration as the display device 2 according to the first embodiment.

Except for Step S6, the display device 2 according to this embodiment can be produced by the same method as the method for producing the display device 2 according to the first embodiment. Moreover, the bank 56 can be formed by the same techniques as the bank 20 is formed; that is, by the same step as Step S6 according to the first embodiment, except for the position in which the bank 56 is formed.

When a voltage is applied to at least one of the third electrode 58 and the fourth electrode 60, each light-emitting element according to this embodiment can generate an electric field between the at least one electrode and another electrode. Thus, in each light-emitting element according to the present embodiment, the third electrode 58 and the fourth electrode 60 can release the carriers trapped in an interface state between the functional layers, so that the light-emitting element can improve light emission efficiency.

Moreover, in this embodiment, the third electrode 58 of the first subpixel SP1 and the fourth electrode 60 of the sixth subpixel SP6 are positioned between the first subpixel SP1 and the sixth subpixel SP6. Furthermore, in this embodiment, the third electrode 58 of the sixth subpixel SP6 and the fourth electrode 60 of the seventh subpixel SP7 are positioned between the sixth subpixel SP6 and the seventh subpixel SP7. In other words, the display device 2 according to this embodiment includes the third electrode 58 and the fourth electrode 60 between adjacent subpixels having the same color.

In this embodiment, each of the subpixels of the display device 2 may be shaped so that the size in the direction in which the subpixels having different colors are adjacent to each other may be larger than the size in the direction in which the subpixels having the same color are adjacent to each other. In this case, the distance between the third electrode 58 and the fourth electrode 60 included in the same light-emitting element is shorter, so that a higher electric field can be applied to the functional layers of the light-emitting element.

### Fifth Embodiment

Changing the Formation Direction of Electrodes and Commonizing Electrodes

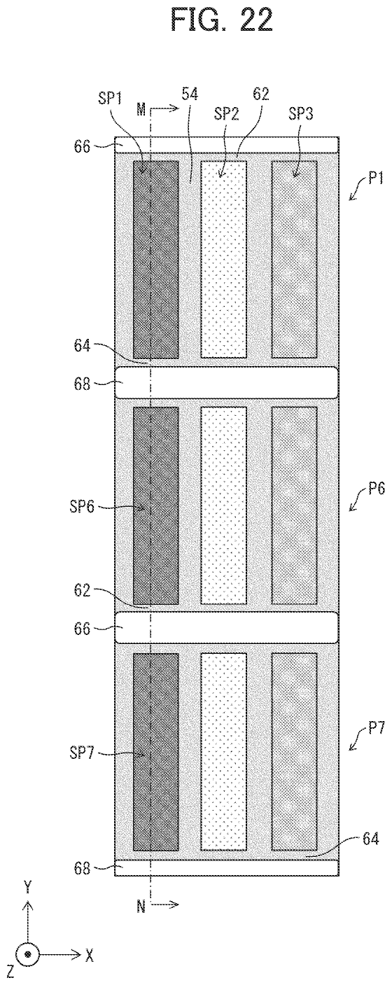

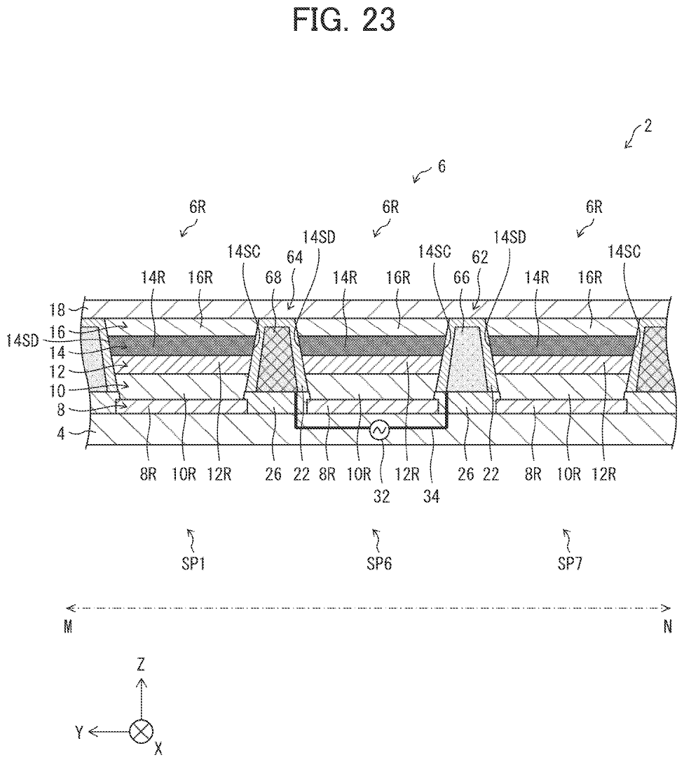

FIG. 22 is an enlarged plan view of a display region of the display device 2 according to this embodiment. FIG. 23 is a schematic cross-sectional view of the display device 2 according to this embodiment, taken along line M-N in FIG. 22.

Compared with the display device 2 according to the previous embodiment, the display device 2 according to this embodiment includes, instead of the bank 56, either a bank 62 or a bank 64 formed between adjacent subpixels having the same color. In other words, compared with each light-emitting element according to the previous embodiment, each light-emitting element according to this embodiment includes, instead of the bank 56, the bank 62 and the bank 64 respectively as the first insulator and the second insulator.

Here, for example, the light-emitting element 6R formed in the sixth subpixel SP6 includes the bank 62 provided toward the first side surface 14SC of the light-emitting layer 14R. Moreover, the light-emitting element 6R formed in the sixth subpixel SP6 includes the bank 64 provided toward the second side surface 14SD of the light-emitting layer 14R. On the other hand, the light-emitting elements 6R formed in the respective first subpixel SP1 and seventh sub-pixel SP7 each include the bank 64 provided toward the first side surface SC of the light-emitting layer 14R. Moreover, the light-emitting elements 6R formed in the respective first subpixel SP1 and seventh subpixel SP7 each include the bank 62 provided toward the second side surface 14SD of the light-emitting layer 14R.

The bank 62 includes, on the mini-bank 26: a third electrode 66; and the first portion 22 covering a side surface and a periphery of the third electrode 66. On the other hand, the bank 64 includes, on the mini-bank 26: a fourth electrode 68; and the first portion 22 covering a side surface and a periphery of the fourth electrode 68. The third electrode 66 and the fourth electrode 68 are electrically connected to the power source 32 respectively through the first wire 34 and the second wire 36. In particular, the third electrode 66 and the fourth electrode 68 are respectively the same in configuration as the third electrode 50 and the fourth electrode 52, except for the positions in which the third electrode 66 and the fourth electrode 68 are formed.

Except for Step S6, the display device 2 according to this embodiment can be produced by the same method as the method for producing the display device 2 according to the previous embodiment. Step S6 according to this embodiment is carried out by forming the bank 62 and the bank 64, using, for example, the same forming method as the method for forming the bank 46 and the bank 48.

The light-emitting element 6R of the sixth subpixel SP6 includes: the third electrode 66 toward the first side surface 14SC across the first portion 22 of the bank 62; and the fourth electrode 68 toward the second side surface 14SD across the first portion 22 of the bank 64. Moreover, the light-emitting elements 6R of the respective first subpixel SP1 and seventh subpixel SP7 each include: the fourth electrode 68 toward the first side surface 14SC across the first portion 22 of the bank 64; and the third electrode 66 toward the second side surface 14SD across the first portion 22 of the bank 62. Furthermore, the power source 32 can apply a voltage to each of the third electrode 66 and the fourth electrode 68 through the first wire 34 and the second wire 36.

Hence, when a voltage is applied to at least one of the third electrode 66 and the fourth electrode 568, each light-emitting element according to this embodiment can generate an electric field between the at least one electrode and another electrode. Thus, in each light-emitting element according to the present embodiment, the third electrode 66 and the fourth electrode 68 can release the carriers trapped in an interface state between the functional layers, so that the light-emitting element can improve light emission efficiency.

Moreover, the bank 62 includes only the third electrode 66 as an electrode, and the bank 64 has only the fourth electrode 68 as an electrode. Furthermore, in the display device 2 according to this embodiment, a light-emitting element and another light-emitting element adjacent to the light-emitting element share either the third electrode 66 or the fourth electrode 68.

For example, the third electrode 66 of the bank 62 illustrated in FIG. 23 functions as a third electrode of the light emitting element 6R in the sixth subpixel SP6, and also functions as a fourth electrode of the light-emitting element 6R in the seventh subpixel SP7. Moreover, the fourth electrode 68 of the bank 64 illustrated in FIG. 23 functions as a third electrode of the light emitting element 6R in the first subpixel SP1, and also functions as a fourth electrode of the light-emitting element 6R in the sixth subpixel SP6.

Hence, compared with the bank 56 including both the third electrode 58 and the fourth electrode 60, not only the structure but also the forming steps of the banks 62 and 64 are simplified. Moreover, between adjacent light-emitting elements, application of a voltage to the third electrode of one of the light-emitting elements can be interpreted as application of a voltage to the fourth electrode of another light-emitting element adjacent to the one light-emitting element. Such a feature of the display device 2 according to the present embodiment can reduce the number of the power sources 32, the first wires 34, and the second wires 36 to be used for applying a voltage to the third electrodes 66 and the fourth electrodes 68.

Each embodiment has described the display device 2 in which a plurality of pixels including a plurality of subpixels are provided in the display region DA. However, the display device 2 shall not be limited to such a configuration, and a light-emitting device including only one light-emitting element according to each embodiment is also included in the present disclosure. The light-emitting element included in the light-emitting device may be any one of the light-emitting element 6R, the light-emitting element 6G, and the light-emitting element 6B according to each embodiment.

The present invention shall not be limited to the embodiments described above, and can be modified in various manners within the scope of claims. The technical aspects disclosed in different embodiments are to be appropriately combined together to implement another embodiment. Such an embodiment shall be included within the technical scope of the present invention. Moreover, the technical aspects disclosed in each embodiment may be combined to achieve a new technical feature.

### REFERENCE SIGNS LIST

2 Display Device
6 Light-Emitting Element Layer
8 Anode (First Electrode)
10 Hole Injection Layer
12 Hole Transport Layer
14 Light-Emitting Layer
14SA First Side Surface
14SB Second Side Surface
16 Electron Transport Layer
18 Cathode (Second Electrode)
20 Bank (First Insulator and Second Insulator)
22 First Portion (Coating Layer)
24 Second Portion (Second Protrusion)
26 Mini-Bank (First Protrusion)
28 Third Electrode
30 Fourth Electrode
32 Power Source
34 First Wire
36 Second Wire

1. A light-emitting element, comprising:
a first electrode serving as an anode;
a second electrode serving as a cathode;
a light-emitting layer positioned between the first electrode and the second electrode;
a first insulator positioned toward a first side surface of the light-emitting layer with respect to the light-emitting layer; and
a third electrode included in the first insulator, and positioned so that a first portion of the first insulator is sandwiched between the third electrode and the first side surface of the light-emitting layer.

2.-3. (canceled)

4. The light-emitting element according to claim 1,
wherein the first portion of the first insulator has a thickness of 10 nm or more and 50 nm or less.

5. (canceled)

6. The light-emitting element according to claim 1, further comprising:
a second insulator positioned toward a second side surface across from the first side surface of the light-emitting layer with respect to the light-emitting layer; and
a fourth electrode included in the second insulator, and positioned so that a third portion of the second insulator is sandwiched between the fourth electrode and the second side surface of the light-emitting layer.

7. The light-emitting element according to claim 6,
wherein the second insulator is made only of a third material.

8. The light-emitting element according to claim 6,
wherein the second insulator is made of: a third material; and a fourth material different from the third material, and
the second insulator includes: the third portion made only of the third material; and a fourth portion containing at least the fourth material.

9. The light-emitting element according to claim 6,
wherein the third portion of the second insulator has a thickness of 10 nm or more and 50 nm or less.

10. (canceled)

11. The light-emitting element according to claim 6,
wherein the light-emitting layer is positioned between the third electrode and the fourth electrode.

12. The light-emitting element according to claim 6, further comprising
a hole transport layer positioned between the first electrode and the light-emitting layer,
wherein the hole transport layer is positioned between the third electrode and the fourth electrode.

13. The light-emitting element according to claim 6, further comprising
an electron transport layer positioned between the second electrode and the light-emitting layer,
wherein the electron transport layer is positioned between the third electrode and the fourth electrode.

14. The light-emitting element according to claim 6,
wherein a surface of the first electrode and a surface of the second electrode toward the light-emitting layer are positioned between the third electrode and the fourth electrode.

15. The light-emitting element according to claim 6,
wherein the first insulator has a first inclined surface covering the first side surface of the light-emitting layer, an edge of the first inclined surface toward the first electrode and an edge of the first inclined surface toward the second electrode are included in a first plane, and the first plane and a second plane in parallel with the first electrode form a first angle,
the second insulator has a second inclined surface covering the second side surface of the light-emitting layer, an edge of the second inclined surface toward the first electrode and an edge of the second inclined surface toward the second electrode are included in a third plane, and the third plane and the second plane form a second angle,
an edge of the third electrode toward the first electrode and an edge of the third electrode toward the second electrode are included in a fourth plane, and the fourth plane and the second plane form a third angle of 90 degrees or larger and the first angle or smaller, and
an edge of the fourth electrode toward the first electrode and an edge of the fourth electrode toward the second electrode are included in a fifth plane, and the fifth plane and the second plane form a fourth angle of 90 degrees or larger and the second angle or smaller.

16.-17. (canceled)

18. A light-emitting device, comprising:
the light-emitting element according to claim 1; and
a first wire capable of applying a first voltage to the third electrode.

19. A light-emitting device, comprising:
the light-emitting element according to claim 6;
a first wire capable of applying a first voltage to the third electrode; and
a second wire capable of applying a second voltage to the fourth electrode.

20.-24. (canceled)

25. A light-emitting device, comprising:
a plurality of the light-emitting elements according to claim 1,
wherein the first insulator is a bank formed between the plurality of light-emitting elements, and dividing the plurality of light-emitting elements from one another.

26. A light-emitting device, comprising:
a plurality of the light-emitting elements according to claim 6,
wherein the second insulator is a bank formed between the plurality of light-emitting elements, and dividing the plurality of light-emitting elements from one another.

27.-29. (canceled)

30. A display device, comprising:
the light-emitting element according to 15 as a first sub-pixel;
the light-emitting element according to claim 15 as a second subpixel adjacent to the first sub-pixel;
the light-emitting element according to claim 15 as a third subpixel adjacent to the second sub-pixel;
the light-emitting element according to claim 15 as a fourth sub-pixel adjacent to the first subpixel; and
the light-emitting element according to claim 15 as a fifth sub-pixel adjacent to the third sub-pixel,
wherein the first subpixel, the second subpixel, and the third subpixel have different colors,
the first subpixel and the fifth subpixel have a same color,
the third subpixel and the fourth subpixel have a same color,
the fourth electrode of the fourth subpixel and the third electrode of the first subpixel, the second subpixel, and the third subpixel are positioned between the fourth subpixel and the first subpixel, and
the fourth electrode of the first subpixel, the second subpixel, and the third subpixel and the third electrode of the fifth subpixel are positioned between the third subpixel and the fifth sub-pixel.

31. A display device, comprising:
the light-emitting element according to 15 as a first sub-pixel;
the light-emitting element according to claim 15 as a second subpixel adjacent to the first sub-pixel;
the light-emitting element according to claim 15 as a third subpixel adjacent to the second sub-pixel;
the light-emitting element according to claim 15 as a fourth sub-pixel adjacent to the first subpixel; and
the light-emitting element according to claim 15 as a fifth sub-pixel adjacent to the third sub-pixel,
wherein the first subpixel, the second subpixel, and the third subpixel have different colors,
the first subpixel and the fifth subpixel have a same color,
the third subpixel and the fourth subpixel have a same color,
the third electrode of the fourth subpixel, the first subpixel, the second subpixel, and the third subpixel are positioned between the fourth subpixel and the first subpixel, and
the fourth electrode of the first subpixel, the second subpixel, the third subpixel, and the fifth subpixel are positioned between the third subpixel and the fifth sub-pixel.

32. A display device, comprising:
the light-emitting element according to 15 as a first sub-pixel;
the light-emitting element according to claim 15 as a second subpixel adjacent to the first sub-pixel;
the light-emitting element according to claim 15 as a third subpixel adjacent to the second sub-pixel;
the light-emitting element according to claim 15 as a sixth sub-pixel adjacent to the first subpixel; and
the light-emitting element according to claim 15 as a seventh sub-pixel adjacent to the sixth sub-pixel,
wherein the first subpixel, the second subpixel, and the third subpixel have different colors,
the first subpixel, the sixth subpixel, and the seventh subpixel have a same color,
the third electrode of the first subpixel and the fourth electrode of the sixth subpixel are positioned between the first subpixel and the sixth subpixel, and
the third electrode of the sixth subpixel and the fourth electrode of the seventh subpixel are positioned between the sixth subpixel and the seventh sub-pixel.

33. A display device, comprising:
the light-emitting element according to 15 as a first sub-pixel;
the light-emitting element according to claim 15 as a second subpixel adjacent to the first sub-pixel;
the light-emitting element according to claim 15 as a third subpixel adjacent to the second sub-pixel;
the light-emitting element according to claim 15 as a sixth sub-pixel adjacent to the first subpixel; and
the light-emitting element according to claim 15 as a seventh sub-pixel adjacent to the sixth sub-pixel,
wherein the first subpixel, the second subpixel, and the third subpixel have different colors,
the first subpixel, the sixth subpixel, and the seventh subpixel have a same color,
the fourth electrode of the first subpixel and the sixth subpixel is positioned between the first subpixel and the sixth subpixel, and
the third electrode of the sixth subpixel and the seventh subpixel is positioned between the sixth subpixel and the seventh sub-pixel.

34. A method for forming an insulator and an electrode on a substrate, the electrode being positioned in the insulator, the method comprising:
a first protrusion forming step of forming a first protrusion;
a second protrusion forming step of forming a second protrusion on an upper surface of the first protrusion;
an electrode forming step of forming the electrode on one side surface or both side surfaces of the second protrusion; and
a coating layer forming step of forming a coating layer to coat the second protrusion and the electrode,
wherein the insulator includes the first protrusion, the second protrusion, and the coating layer.

35. (canceled)
